(19) United States
(12) Patent Application Publication
(10) Pub. No.: US 2022/0228044 A1
(43) Pub. Date: Jul. 21, 2022

(54) WATER-BASED TEMPORARY FIXING ADHESIVE, AND METHOD FOR PRODUCING VARIOUS MEMBERS OR PARTS USING SAID WATER-BASED TEMPORARY FIXING ADHESIVE

(71) Applicant: DNP FINE CHEMICALS CO., LTD., Yokohama-shi, Kanagawa (JP)

(72) Inventor: Kunihiko ODAGIRI, Tsukuba-shi (JP)

(73) Assignee: DNP FINE CHEMICALS CO., LTD., Yokohama-shi, Kanagawa (JP)

(21) Appl. No.: 17/614,717

(22) PCT Filed: Jun. 2, 2020
(86) PCT No.: PCT/JP2020/021796

§ 371 Date: Nov. 29, 2021

(30) Foreign Application Priority Data
Jun. 3, 2019 (JP) 2019-103741

(51) Int. Cl. C09J 171/02; C09J 11/06; H01L 21/683; H01L 21/304; B24B 37/04

(52) U.S. Cl. CPC C09J 171/02; C09J 11/06; H01L 21/6836; H01L 2221/68327; B24B 37/042; C09J 2471/00; H01L 21/304

(57) ABSTRACT

A water-based temporary fixing adhesive having excellent temporary fixing performance, coating performance and adhesion-stain prevention performance and containing (A) a hydroxy group-having thermoplastic resin and (B) a glucide, wherein the glucide (B) is at least one selected from sugars and sugar alcohols; and a method for producing a member or a part including a temporary fixing step of temporarily fixing a precursor of a member or a part and a processing substrate using the adhesive, and a processing step of mechanically processing the precursor to form a member or a part.

### TECHNICAL FIELD

The present invention relates to a water-based temporary fixing adhesive, and a method for producing various members or parts using the water-based temporary fixing adhesive.

### BACKGROUND ART

Adhesives are used in various applications widely including not only home applications but also various industrial applications such as production of various members and parts (hereinafter these may be referred to as “adherends”) used in various electronic devices such as OA devices, information devices and home electric appliances, and in other various devices such as optical devices, medical devices and automobile devices. The performance originally required for adhesives is, needless-to-say, adhesion performance but depending on the application, adhesives may often be required to exhibit adhesion performance in temporarily fixing one or plural members or parts and to exhibit peel performance in thereafter peeling them (hereinafter this may be referred to as “temporary fixing performance). For example, regarding optical lenses for use in optical devices, adhesives to be used in producing such optical lenses that are produced by temporarily fixing a lens material on a support, then processing it in various mechanical processes such as machining, polishing, cutting, grinding and drilling to give a predetermined shape and a surface profile thereto, and thereafter peeling them from the support are required to have temporary fixing performance.

Also in mechanically processing members such as wafers that are members for semiconductor devices for use in electronic devices, a method of producing them by temporarily fixing a member material on a support, then processing it in various mechanical processes such as machining, polishing, cutting, grinding and drilling to give a predetermined shape and a surface profile thereto, and thereafter peeling them from the support is employed, like in production of optical lenses mentioned above (for example, PTL 1), and adhesives to be used in the method are also required to have temporary fixing performance. Apart from that for optical lenses and wafers, in various mechanical processes such as machining, polishing, cutting, grinding and drilling of others such as sapphire, gallium arsenide, quartz, magnetic members, metal members, glass members, resin members and members for semiconductor devices, an adhesive having temporary fixing performance (hereinafter this may be referred to as “temporary fixing adhesive”) can be used as the case may be.

The temporary fixing adhesive described in PTL 1 is an organic solvent-based adhesive containing a cycloolefin polymer and a UV absorbent and therefore needs to be removed in peeling the adherend, using a different organic solvent, or to be removed using an acidic detergent such as a strong acid. However, with recent increase in environment and safety consciousness, and from the viewpoint of reducing the load on the environment such as that on the natural environment of air pollution and that on the working environment, and from the viewpoint of safety, an adhesive that refrains from using an organic solvent as much as possible has become required, and not those containing an organic solvent such as the adhesive described in PTL 1 but a water-based temporary fixing adhesive has become desired (for example, PTL 2). PTL 2 describes a water-peeling energy ray-curable adhesive that contains a water-soluble resin having a photopolymerizing oxirane ring, and when such a water-based temporary fixing agent is used, adherends can be readily removed by immersion in water or warm water.

Recently, improvements such as reduction in thickness, reduction in size and reduction in weight of the above-mentioned various devices have been advanced, and similar improvements have become required for various members and parts used in various devices, and in that situation, a higher accuracy has become required for various mechanical processing such as machining, polishing, cutting, grinding and drilling. However, though the water-based adhesive described in PTL 2 is preferable in terms of low load on environments such as natural environment and working environment, some problems about the adhesive have become obvious in point of coating performance thereof such that owing to poor compatibility with adherends and presence of minute foreign matters attached to the surfaces of adherends, the adherend could not apply even to the outer peripheries of adherends, and in point of occurrence of adhesion stains such that, even though the adhesive could be applied to the outer peripheries of adherends, the thickness thereof could not be made uniform. In the case where such adhesion stains have occurred, airtight adhesiveness between supports and adherends becomes poor in machine processing and therefore temporary fixing is insufficient and adhesion strength lowers, therefore often causing a problem of temporary fixing performance degradation and even a problem of reduction in processing accuracy. Consequently, a water-based temporary fixing adhesive has become required to satisfy not only temporary fixing performance but also coating performance that enables applicability even to the outer peripheries of adherends, and further also adhesion-stain prevention performance that enables uniform coating to prevent occurrence of adhesion stains.

### CITATION LIST

### Patent Literature

PTL 1: JP 2013-33814 A
PTL 2: JP 2004-35866

### SUMMARY OF INVENTION

### Technical Problem

The present invention has been made under such situations, and an object thereof is to provide a water-based temporary fixing adhesive having excellent temporary fixing performance, coating performance and adhesion-stain prevention performance, and to provide a method for producing various members or parts using the water-based temporary fixing adhesive.

### Solution to Problem

The present inventor has repeated assiduous studies for solving the above-mentioned problems and, as a result, has found that the problems can be solved by the following invention. Specifically, the present invention provides a water-based temporary fixing adhesive having the following constitution.

1. A water-based temporary fixing adhesive containing (A) a hydroxy group-having thermoplastic resin and (B) a glucide, wherein the glucide (B) is at least one selected from sugars and sugar alcohols.
2. A method for producing a member or a part including a temporary fixing step of temporarily fixing a precursor of a member or a part and a processing substrate using the water-based temporary fixing adhesive described in the above 1, and a processing step of mechanically processing the precursor to form a member or a part.

### Advantageous Effects of Invention

According to the present invention, there can be provided a water-based temporary fixing adhesive having excellent temporary fixing performance, coating performance and adhesion-stain prevention performance, and also a method for producing various members or parts using the water-based temporary fixing adhesive.

### DESCRIPTION OF EMBODIMENTS

Hereinunder the water-based temporary fixing adhesive of the present invention is described. In this description, the upper limit and lower limit numerical values of “X or more”, “Y or less” and “X to Y” relating to the description of a numerical range are numerical values that can be combined in any manner, and the numerical values in Examples can be the upper limit and the lower limit.

### [Water-based Temporary Fixing Adhesive]

The water-based temporary fixing adhesive of the present invention can be used as a water-based adhesive, and as containing (A) a hydroxy group-having thermoplastic resin that exhibits temporary fixing performance satisfying both adhesion performance and peeling performance (hereinafter this may be referred to as “component (A)”), this has excellent temporary fixing performance though being a water-based adhesive, and further as combined with (B) a glucide (hereinafter this may be referred to as “component (B)”), this can be a water-based temporary fixing adhesive characterized by further satisfying both coating performance and adhesion-stain prevention performance in addition to excellent temporary fixing performance.

Hereinafter the constituent components that the water-based temporary fixing adhesive of the present invention contains are described.

### ((A) Hydroxy Group-Having Thermoplastic Resin)

The hydroxy group-having thermoplastic resin (A) contained in the water-based temporary fixing adhesive of the present invention is a component mainly expressing temporary fixing performance that has both adhesion performance and peeling performance.

Not specifically limited, the resin contained in the hydroxy group-having thermoplastic resin (A) may be any thermoplastic resin having a hydroxy group in the molecule, but is preferably one having a melting point of 30° C. or higher. When the resin contained in the hydroxy group-having thermoplastic resin (A) has a melting point of 30° C. or higher, the melting point of the water-based temporary fixing adhesive of the present invention can be readily 30° or higher, and not only temporary fixing performance but also general versatility thereof can improve. From the same viewpoint, the melting point of the resin contained in the hydroxy group-having thermoplastic resin (A) is more preferably 35° C. or higher, even more preferably 37° C. or higher, still more preferably 40° C. or higher, especially more preferably 43° C. or higher. The upper limit is preferably 200° C. or lower, more preferably 180° C. or lower, even more preferably 160° C. or lower, further more preferably 120° C. or lower, especially more preferably 100° C. or lower. When the upper limit of the melting point of the component (A) is 200° C. or lower, temporary fixing performance of the water-based temporary fixing adhesive of the present invention improves owing to improvement of peeling performance thereof, and additionally, coating performance and general versatility thereof also improve.

In this description, the melting point of the component (A) means an end point of melting measured according to JIS K0064:1992. Specific measurement thereof will be described hereinunder.

The number-average molecular weight of the resin contained in the hydroxy group-having thermoplastic resin (A) is, from the viewpoint of improving both coating performance and cissing prevention performance along with temporary fixing performance, preferably 800 or more, more preferably 1,000 or more, even more preferably 1,200 or more, especially more preferably 1,400 or more, and the upper limit is preferably 25,000 or less, more preferably 20,000 or less, even more preferably 15,000 or less, especially more preferably 10,000 or less. In this description, the number-average molecular weight is measured through gel permeation chromatography (GPC) using polystyrene as a standard substance.

The resin contained in the hydroxy group-having thermoplastic resin (A) having the above-mentioned properties is, from the viewpoint of attaining more excellent temporary fixing performance, preferably a thermoplastic resin having an oxyalkylene group, more preferably a resin having one type of an oxyalkylene group as a constituent unit.

The oxyalkylene group is preferably one having a carbon number of 1 or more, more preferably 2 or more, and the upper limit is preferably 12 or less, more preferably 8 or less, even more preferably 4 or less, especially more preferably 3 or less.

The recurring unit number of the oxyalkylene group is preferably 10 or more, more preferably 30 or more, even more preferably 50 or more, and the upper limit is preferably 500 or less, more preferably 300 or less, even more preferably 150 or less.

More specifically, as the oxyalkylene group-having thermoplastic resin preferably, preferred are a polyalkylene glycol, a polyoxyalkylene ester, a polyoxyalkylene alkyl ether, and an polyoxyalkylene alkyl aryl ether, more preferred are a polyalkylene glycol, a polyoxyalkylene ester, and a polyoxyalkylene alkyl ether, even more preferred are a polyalkylene glycol and a polyoxyalkylene ester, and especially more preferred is a polyalkylene glycol. One alone or plural kinds of these thermoplastic resins can be used either singly or as combined.

As the polyalkylene glycol, preferred are a polyethylene glycol, a polypropylene glycol, and a polybutylene glycol, more preferred are a polyethylene glycol and a polypropylene glycol, and even more preferred is a polyethylene glycol.

As the polyoxyalkylene ester, preferred is an ester of a fatty acid having 12 or more and 24 or less carbon atoms, and more specifically, preferred are a polyoxyalkylene monoester such as a polyethylene glycol monolaurate, a polyethylene glycol monostearate, a polyethylene glycol monooleate, a polypropylene glycol monolaurate, a polypropylene glycol monostearate and a polypropylene glycol monooleate, and a polyoxyalkylene diester such as a polyethylene glycol distearate and a polyethylene glycol dioleate, more preferred is a polyoxyalkylene monoester, even more preferred is a polyoxyethylene monoester, and especially more preferred is a polyoxyethylene monostearate.

As the polyoxyalkylene alkyl ether, preferred is one having an alkyl group having 12 or more and 24 or less carbon atoms, and more specifically, preferred are a polyoxyethylene oleyl ether, a polyoxyethylene lauryl ether, a polyoxypropylene oleyl ether, and a polyoxypropylene lauryl ether.

As the polyoxyalkylene alkyl aryl ether, preferred is one having an alkyl aryl group having 12 or more and 24 or less carbon atoms, and more specifically, preferred are a polyoxyethylene octyl phenyl ether, a polyoxyethylene nonyl phenyl ether, a polyoxypropylene octyl phenyl ether, and a polyoxypropylene nonyl phenyl ether.

In the present invention, the hydroxy group-having thermoplastic resin (A) preferably contains at least a resin having a predetermined melting point and a predetermined number average molecular weight as exemplified in the above, and further an oxyalkylene group-having resin, and a resin having one type of an oxyalkylene group as a constituent unit, and though it may contain any other resin than those exemplified in the above, but preferably, all the resins contained are the above-exemplified resins.

In the present invention, from the viewpoint of improving both temporary fixing performance and coating performance, one type of a thermoplastic resin may be used as the hydroxy group-having thermoplastic resin (A), but two or more types of thermoplastic resins differing in the number-average molecular weight, for example, two or more types of polyalkylene glycols differing in the number-average molecular weight may also be used. In that case, for example, paying attention to temporary fixing performance and from the viewpoint of especially improving the performance, preferably, a polyalkylene glycol having a number average molecular weight of 800 or more and less than 5,000 (hereinafter this may be referred to as “polyalkylene glycol A1”) and a polyalkylene glycol having a number-average molecular weight of 5,000 or more and 10,000 or less (hereinafter this may be referred to as “polyalkylene glycol B1”) are combined, and more preferably, a polyethylene glycol having a number-average molecular weight of 800 or more and less than 5,000 and a polyethylene glycol having a number-average molecular weight of 5,000 or more and 10,000 or less are combined.

Also for example, paying attention to coating performance and from the viewpoint of especially improving the performance, preferably, a polyalkylene glycol having a number-average molecular weight of 800 or more and less than 2,500 (hereinafter this may be referred to as “polyalkylene glycol A2”) and a polyalkylene glycol having a number-average molecular weight of 2,500 or more and 10,000 or less (hereinafter this may be referred to as “polyalkylene glycol B2”) are combined, and more preferably, a polyethylene glycol having a number average molecular weight of 800 or more and less than 2,500 and a polyethylene glycol having a number-average molecular weight of 2,500 or more and 10,000 or less are combined.

The blending ratio (ratio by mass) of the polyalkylene glycol A1 and the polyalkylene glycol B1, as well as the blending ratio (ratio by mass) of the polyalkylene glycol A2 and the polyalkylene glycol B2 is preferably 10/90 to 90/10, more preferably 15/85 to 85/15, even more preferably 20/80 to 80/20. When the blending ratio falls within the above range, the thickness of a coating film of the water-based temporary fixing adhesive can be readily secured to attain more stable adhesion performance, and accordingly, temporary fixing performance improves and coating performance also improves to facilitate formation of a coating film having a uniform thickness and, as a result, adhesion performance especially improves.

The content of the hydroxy group-having thermoplastic resin (A) in the water-based temporary fixing adhesive is preferably 5% by mass or more, more preferably 10% by mass or more, even more preferably 12% by mass or more, especially more preferably 15% by mass or more, and the upper limit is preferably 50% by mass or less, more preferably 47% by mass or less, even more preferably 45% by mass or less, especially more preferably 42% by mass or less. When the content of the thermoplastic resin falls within the above range, the thickness of a coating film of the water-based temporary fixing adhesive can be readily secured to attain more stable adhesion performance, and accordingly, temporary fixing performance also improves.

### ((B) Glucide)

The glucide (B) contained in the water-based temporary fixing adhesive of the present invention is a component which, mainly as combined with the hydroxy group-having thermoplastic resin (A), can reduce adhesion stains and can achieve the uniformity in the thickness of a coating film to thereby improve adhesion performance especially among temporary fixing performance. Specifically, the component (B) is a component which, as combined with the component (A), can attain especially excellent adhesion-stain prevention performance to thereby improve adhesion performance especially among temporary fixing performance.

Up to now, in processing members or parts by temporary fixation, adhesive stains can be visually recognized on the adhered faces of the processed members or parts in peeling them after the processing in some cases, though not noticed at the time of temporary fixation. The water-based temporary fixing adhesive of the present invention using the component (B) can reduce occurrence of such fine adhesion stains that could not be visually recognized from the surface condition of such temporarily-fixed members or parts, and can have extremely excellent adhesion-stain prevention performance.

The glucide (B) is at least one selected from sugars and sugar alcohols.

Preferred examples of the sugars include glucose, fructose, galactose, mannose, sucrose, lactose, maltose, trehalose and palatinose.

Preferred examples of the sugar alcohols include sorbitol, mannitol, maltitol, xylitol, erythritol, pentaerythritol and lactitol.

One or plural kinds of these glucides can be used either singly or as combined.

Among the above-mentioned glucides, from the viewpoint of improving adhesion-stain prevention performance and improving especially adhesion performance among temporary fixing performance, sugars or sugar alcohols are preferably contained, and combined use of sugars and sugar alcohols is preferred. More preferred are sugar alcohols, that is, the total amount is more preferably a sugar alcohol.

Also from the same viewpoint, as sugar alcohols, preferred are erythritol, pentaerythritol, xylitol, sorbitol, maltitol, lactitol and mannitol, and more preferred are maltitol, lactitol and mannitol, and even more preferred is mannitol.

The content of the glucide (B) in the water-based temporary fixing adhesive is, from the viewpoint of improving adhesion-stain prevention performance and improving especially adhesion performance among temporary fixing performance, preferably 0.1% by mass or more, more preferably 0.5% by mass or more, even more preferably 1.0% by mass or more, further more preferably 2.0% by mass or more, and the upper limit is preferably 15.0% by mass or less, more preferably 12.0% by mass or less, even more preferably 10.0% by mass or less, further more preferably 7.0% by mass or less.

### (Solvent)

The water-based temporary fixing adhesive of the present invention can be used by dissolving the above component (A) and component (B) in a solvent. Water can be used as the solvent, and for example, ion-exchanged water can be used. In the present invention, as the solvent, any other solvent than water, for example, various organic solvents can be used, but in consideration of reducing the load on natural environments and working environment and securing safety, preferably, the organic solvent is not contained. Specifically, the first water-based temporary fixing adhesive of the present invention is preferably a substantially completely water-based temporary fixing adhesive not containing an organic solvent.

Here, “not containing an organic solvent” means that the content of an organic solvent is 0% by weight and, in addition thereto, the adhesive does not intentionally contain an organic solvent. For example, it means that presence of an organic solvent that is inevitably contained in the component (A) and the component (B) is accepted, and in that case, the content of the organic solvent contained in all the solvents is preferably 5% by mass or less, more preferably 2% by mass or less, eve more preferably 1% by mass or less, further more preferably 0.5% by mass or less, especially more preferably 0.1% by mass or less.

### (Other Additives)

The water-based temporary fixing adhesive of the present invention may optionally contain any other additive than the above-mentioned components, such as an antifoaming agent, a leveling agent, a silane coupling agent, a crystal nucleating agent, a plasticizer, a preservative, and an antioxidant.

### (Properties of Water-Based Temporary Fixing Adhesive)

Regarding the properties of the water-based temporary fixing adhesive of the present invention, the melting point is preferably 30° C. or higher, more preferably 35° C. or higher, even more preferably 37° C. or higher, further more preferably 40° C. or higher, especially more preferably 43° C. or higher. The upper limit is preferably 200° C. or lower, more preferably 180° C. or lower, even more preferably 160° C. or lower, further more preferably 120° C. or lower, especially more preferably 100° C. or lower. When the melting point of the water-based temporary fixing adhesive falls within the above range, not only adhesion performance but also peeling performance of the water-based temporary fixing adhesive improves to therefore improve temporary fixing performance thereof, and even general versatility can also improve.

In this description, the melting point means an end point of melting measured according to JIS K0064:1992 (Method for Measurement of Melting Point and Melting Range of Chemical Products). Specifically, the water-based temporary fixing adhesive heated and melted (temperature condition: 30 to 90° C.) and then cooled (temperature condition: −20 to 30° C.) is ground into a fine powder (maximum particle size: 300 μm), the resultant powder is, as needed, after dried in a desiccator for 24 hours, used as a sample, and based on “4. Melting Range Measurement Method” defined in JIS K0064:1992 (Method for Measurement of Melting Point and Melting Range of Chemical Products), the sample is filled in a capillary tube (made of glass, inner diameter: 0.8 to 1.2 mm, thickness: 0.2 to 0.3 mm, length; 150 mm), and heated at a heating speed of 1° C./min. The melting temperature at which any solid is no more recognized in visual observation (the temperature at which the powdery solid sample has completely liquefied) is referred to as the melting point of the water-based temporary fixing adhesive.

### (Regarding Preferred Embodiments of Water-Based Temporary Fixing Adhesive)

The water-based temporary fixing adhesive of the present invention, as containing the above-mentioned (A) hydroxy group-having thermoplastic resin and (B) glucide, can have excellent temporary fixing performance, coating performance and adhesion-stain prevention performance. Depending on the use and the desired performance thereof, the water-based temporary fixing adhesive of the present invention preferably includes, for example, the following embodiments.

First embodiment: The water-based temporary fixing adhesive further containing (C1) a surface conditioner and (D1) a compatibilizer.

Second embodiment: The water-based temporary fixing adhesive wherein the total content of a sodium metal ion, an aluminum metal ion, an iron metal ion, a zinc metal ion, a copper metal ion, a nickel metal ion, a chromium metal ion and a lead metal ion is 3000 ppb or less, and the content of the sodium metal ion, the iron metal ion, the zinc metal ion and the copper metal ion is each individually 1000 ppb or less.

Third embodiment: The water-based temporary fixing adhesive further containing (C3) a water-containing solvent in which the content of water in the solvent is 95% by mass or more, and having a surface tension at 25° C. of 20 mN/m or more and 55 mN/m or less and an adhesion strength of 0.1 MPa or more and 20 MPa or less.

Hereinunder the water-based temporary fixing adhesive of the first embodiment (this may be hereinafter referred to as “first water-based temporary fixing adhesive”) is first described. The water-based temporary fixing adhesive of the second embodiment and the water-based temporary fixing adhesive of the third embodiment may be hereinafter referred to as “second water-based temporary fixing adhesive” and “third water-based temporary fixing adhesive”, respectively.

### <First Water-Based Temporary Fixing Adhesive>

The first water-based temporary fixing adhesive further contains (C1) a surface conditioner and (D1) a compatibilizer, in addition to the above-mentioned (A) hydroxy group-having thermoplastic resin and (B) glucide.

The surface conditioner (C1) that is additionally contained (hereinafter this may be referred to as “component (C1)”) is a component mainly expressing coating performance, and the compatibilizer (D1) (hereinafter this may be referred to as “component (D1)”) is a component mainly improving the compatibility between the component (A) and the component (B) to thereby express cissing prevention performance. Further, the given cissing prevention performance can reduce coating unevenness to thereby more improve adhesion-stain prevention performance, and in addition, the thickness of the coating film can be more uniform to improve adhesion performance among temporary fixing performance.

The first water-based temporary fixing adhesive contains four components of the above-mentioned component (A), component (B), component (C1) and component (D1) as combined, and can therefore satisfy cissing prevention performance in addition to excellent temporary fixing performance, coating performance and adhesion-stain prevention performance. In addition, coating performance to be caused by the compatibility resulting from difference in materials and surface properties between the temporary fixing adhesive and the adherend, and also heat resistance against heating in mechanical processing can also improve, and accordingly, occurrence of misalignment and peeling of the adherend from the support in processing can be prevented to improve adhesion performance and to attain general versatility that can accommodate temporary fixing of various adherends.

### ((C1) Surface Conditioner)

The surface conditioner (C1) contained in the first water-based temporary fixing adhesive is a component mainly expressing coating performance, especially coating performance for adherends such as wafers. With no specific limitation, the surface conditioner (C1) for use herein may be any one generally having capabilities of solving the defects of coating films to be caused by viscosity change owing to molecular weight increase, by surface tension change or by surface foaming and called a surface conditioner, a leveling agent, a wetting agent or an antifoaming agent, and preferred examples thereof include various surface conditioners, leveling agents, wetting agents and antifoaming agents such as acrylic, vinylic, silicone-based, fluorine-based, cellulosic or natural wax-based water-soluble organic solvents, and in addition thereto, surfactants are also preferred. Above all, surfactants, especially nonionic surfactants are preferred.

More specifically, nonionic surfactants for use herein include acetylene bond-having acetylene-based surfactants such as acetylene alcohol-based surfactants and acetylene glycol-based surfactants, as well as other nonionic surfactants such as fluorine-based surfactants, fatty acid monoglycerides, sorbitan fatty acid esters, sucrose fatty acid esters, polyoxyethylene sorbitan fatty acid esters and polyoxyethylene-added acetylene glycols. Among these, especially preferred are acetylene bond-having acetylene-based surfactants such as acetylene alcohol-based surfactants and acetylene glycol-based surfactants, and also fluorine-based surfactants, and more preferred are acetylene-based surfactants. In the present invention, as the surface conditions (C1), one or plural kinds of the above can be used either singly or as combined.

As the acetylene bond-having acetylene-based surfactants such as acetylene alcohol-based surfactants and acetylene glycol-based surfactants, more specifically, preferred are acetylene alcohol-based surfactants represented by the following general formula (1) and acetylene glycol-based surfactants represented by the following general formula (2).

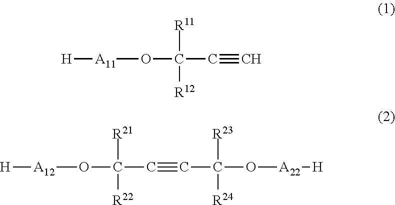

In the general formula (1), R¹¹ and R¹² each independently represent a hydrocarbon group having 1 or more and 8 or less carbon atoms, A₁₁ represents a single bond or an oxyalkylene group having 1 or more and 30 or less recurring units. In the general formula (2), R²¹, R²², R²³ and R²⁴ each independently represent a hydrocarbon group having 1 or more and 8 or less carbon atoms, A₂₁ and A₂₂ each independently represent a single bond or an oxyalkylene group having 1 or more and 30 or less recurring units.

As the hydrocarbon group of R¹¹, R¹², R²¹, R²², R²³ and R²⁴, preferred are an alkyl group and an alkenyl group, more preferred is an alkyl group. These hydrocarbon groups may be linear or branched. The upper limit of the carbon number is preferably 6 or less, more preferably 4 or less.

In the case where A₁₁, A₂₁ and A₂₂ each are an oxyalkylene group having 1 or more and 30 or less recurring units, the acetylene alcohol-based surfactant represented by the general formula (1) is an acetylene alcohol alkylene oxide adduct, and the acetylene glycol-based surfactant represented by the general formula (2) is an acetylene glycol alkylene oxide adduct.

The recurring unit number of A₁₁, A₂₁ and A₂₂ is preferably 2 or more, more preferably 3 or more, and the upper limit is preferably 24 or less, more preferably 12 or less, even more preferably 8 or less, especially more preferably 6 or less.

The carbon number of the oxyalkylene group of A₁₁, A₂₁ and A₂₂ is preferably 1 or more, more preferably 2 or more, and the upper limit of the carbon number is 12 or less, more preferably 8 or less, even more preferably 4 or less, especially more preferably 3 or less. The alkylene group may be linear or branched.

In the case where the recurring unit number of A₁₁, A₂₁ and A₂₂ is 2 or more, plural A₁₁, A₂₁ and A₂₂ may be the same or different. For example, A₁₁ may be one formed by linking an oxyethylene group and an oxypropylene group, and the same shall apply to A₂₁ and A₂₂.

In the present invention, among the acetylene-based surfactants, preferred are the acetylene glycol-based surfactants represented by the general formula (2), more preferred are acetylene glycol alkylene oxide adducts in which at least one of A₂₁ and A₂₂ is an oxyalkylene group having 1 or more and 30 or less recurring units, and even more preferred are acetylene glycol alkylene oxide adducts in which A₂₁ and A₂₂ each are an oxyalkylene group having 1 or more and 30 or less recurring units.

The acetylene-based surfactants are available as commercial products, and examples thereof include Surfynol 104E, 10411, 104A, 104PA, 104PG-50, 104S, 420, 440, 465, 485, SE, SE-F, PSA-336, DF-110, DF37, and Olfine E1004, E1006, E1010, E1020, E1030W, EXP.4001, EXP.4200, EXP.4300, PD-002W, SPC, AF-103, AK-02 (all by Nissin Chemical Industry Co., Ltd.).

The fluorine-based surfactants include oligomers containing a fluorine-containing group and an lipophilic group, and oligomers containing a fluorine-containing group, a hydrophilic group and an lipophilic group. The oligomers containing a fluorine-containing group and an lipophilic group are available as commercial products, and examples thereof include Megafac F-569, F-574 (both by DIC Corporation); and the oligomers containing a fluorine-containing group, a hydrophilic group and an lipophilic group are also available as commercial products, and examples thereof include Megafac F-477, F-553, F-556, R-94, F-559 (all by DIC Corporation).

The fluorine-based surfactants include partially fluorinated alcohol-substituted glycols represented by the following general formula (3). Such fluorine-based surfactants are available as commercial products, including Capstone FS-3100, FS-30, FS-31, FS-34, FS-35 (all by DuPont Corporation).

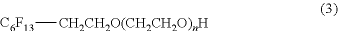

wherein n represents an integer of 1 or more and 40 or less.

The fluorine-based surfactants include partially fluorinated alcohols, and are available as commercial products such as Capstone FS-65 (by DuPont Corporation).

As the surface conditioner (C1), surface conditioners such as acrylic surface conditioners are also preferably used. The acrylic surface conditioners include acrylic copolymers such as poly(meth)acrylates and modified poly(meth)acrylates, and are, for example, available as commercial products such as BYK-381, BYK-3440, BYK-3441 (all by BYK Japan KK).

As the surface conditioner (C1), from the viewpoint of improving cissing prevention performance along with temporary fixing performance and coating performance, preferred are surface conditioners such as acetylene bond-having acetylene-based surfactants, e.g., acetylene alcohol-based surfactants and acetylene glycol-based surfactants, as well as fluorine-based surfactants and acrylic surface conditioners; and more preferred are acetylene-based surfactants, fluorine-based surfactants and acrylic surface conditioners. The fluorine-based surfactants include both nonionic ones and ampholytic ones, but from the viewpoint of improving cissing prevention performance along with temporary fixing performance and coating performance, preferred are nonionic ones.

In the present invention, the surface conditioner (C1) preferably contains at least any of the above-mentioned surface conditioners, and may contain any other than the above-mentioned ones, but preferably, all contained therein are any of the above-mentioned surface conditioners.

The content of the surface conditioner (C1) in the water-based temporary fixing adhesive is, from the viewpoint of improving cissing prevention performance along with temporary fixing performance and coating performance, preferably 0.01% by mass or more, more preferably 0.03% by mass or more, even more preferably 0.05% by mass or more, especially more preferably 0.10% by mass or more, and the upper limit is preferably 5% by mass or less, more preferably 3% by mass or less, even more preferably 1.5% by mass or less, especially more preferably 1% by mass or less.

### ((D1) Compatibilizer)

The compatibilizer (D1) contained in the first water-based temporary fixing adhesive is a component mainly improving the compatibility between the hydroxy group-having thermoplastic resin (A) and the surface conditioner (C1) to express cissing prevention performance. The component (A) contains a hydroxy group and exhibits hydrophilicity, while on the other hand, the surface conditioner (C1) tends to exhibit hydrophobicity, and therefore it cannot be said that the component (A) and the component (C1) have high compatibility with each other. Consequently, when the component (A) and the component (C1) are used together, a part of the coating film of the adhesive may be a cissing part having a small coating amount of the adhesive or not coated with the adhesive, and if so, the adhesive could hardly be uniformly applied onto adherends such as wafers. Accordingly, in the present invention, the compatibilizer (D1) is used to improve the compatibility between the component (A) and the component (C1) to make it possible to attain cissing prevention performance along with excellent temporary fixing performance, coating performance and adhesion-stain prevention performance.

Not specifically limited, the compatibilizer (D1) may be any compound having compatibilization performance to improve the compatibility between the hydrophilic component (A) and the hydrophobic component (C1), and for example, a compound having a hydrophilic moiety and a hydrophobic moiety in the molecule is preferably used. As such a compound, preferred is an alkylene oxide copolymer. The alkylene oxide is an alkylene oxide preferably having 2 or more and 8 or less carbon atoms, more preferably 2 or more and 4 or less carbon atoms, and examples thereof include ethylene oxide, 1,2-propylene oxide, 1,3-propylene oxide, 1,2-butylene oxide, 2,3-butylene oxide, 1,3-butylene oxide, and tetrahydrofuran. Above all, a combination of ethylene oxide and propylene oxide is preferred.

The alkylene oxide copolymer may be any of a random-type, block-type or graft-type one, but from the viewpoint of expressing more excellent compatibilization performance and improving cissing performance, a block-type one is preferred.

Among the above-mentioned alkylene oxide copolymers, preferred is a copolymer of ethylene oxide and propylene oxide (hereinafter this may be referred to as “ethylene oxide-propylene oxide copolymer”); and more preferred is a block copolymer of ethylene oxide and propylene oxide (hereinafter this may be referred to as “ethylene oxide-propylene oxide block copolymer”). Among the ethylene oxide-propylene oxide block copolymer, especially preferred are a triblock copolymer having a propylene oxide chain as the main chain and having an ethylene oxide chain at both ends thereof (hereinafter this may be referred to as “ethylene oxide-propylene oxide-ethylene oxide triblock copolymer”), and a triblock copolymer having an ethylene oxide chain as the main chain and having a propylene oxide chain at both ends thereof (hereinafter this may be referred to as “propylene oxide-ethylene oxide-propylene oxide triblock copolymer”). The ethylene oxide-propylene oxide block copolymer, especially the ethylene oxide-propylene oxide-ethylene oxide triblock copolymer and the propylene oxide-ethylene oxide-propylene oxide triblock copolymer can exhibit hydrophilicity at the ethylene oxide chain moiety and hydrophobicity at the propylene oxide chain moiety, and therefore can express more remarkably the compatibilization performance to improve the compatibility between the hydrophilic component (A) and the hydrophobic component (C1), thereby attaining more excellent cissing prevention performance.

As the ethylene oxide-propylene oxide block copolymer, also preferred is a diblock copolymer of ethylene oxide and propylene oxide (hereinafter this may be referred to as “ethylene oxide-propylene oxide diblock copolymer”). Like in the above-mentioned triblock copolymer, the ethylene oxide chain moiety in the diblock copolymer exhibits hydrophilicity and the propylene oxide chain moiety therein exhibits hydrophobicity, and therefore the diblock copolymer of the type can more remarkably express the compatibilization performance to improve the compatibility between the hydrophilic component (A) and the hydrophobic component (C1), thereby attaining more excellent cissing prevention performance.

Alkylene oxide copolymers such as the ethylene oxide-propylene oxide-ethylene oxide triblock copolymer and the propylene oxide-ethylene oxide-propylene oxide triblock copolymer are available as commercial products, for example, as Newpol PE61, 62, 64, 68, 71, 74, 75, 78, 108, 128 (all by Sanyo Chemical Industries, Ltd.), Pluronic P85, F88, F108 (all by ADEKA Corporation), Unilube 70DP-600B, 70DP-950B, Pronon #208, Pronon #238, Pronon #357 (all by NOF Corporation), and Epan 485, Epan 680, Epan 785, Epan U-108 (all by DKS Co., Ltd).

In the ethylene oxide-propylene oxide copolymer, the ratio of the propylene oxide to the ethylene oxide is preferably 10% by mass or more, more preferably 15% by mass or more, even more preferably 20% by mass or more, and the upper limit is preferably 300% by mass or less, more preferably 200% by mass or less, even more preferably 100% by mass or less. When the ratio of the propylene oxide to the ethylene oxide falls within the above range, more excellent compatibilization can be attained and, as a result, more excellent cissing prevention performance can be thereby attained.

In the case where the compatibilizer (D1) is an alkylene oxide copolymer, the number-average molecular weight thereof is preferably 5,000 or more, more preferably 6,000 or more, even more preferably 7,000 or more, especially more preferably 8,000 or more, and the upper limit is preferably 500,000 or less, more preferably 250,000 or less, even more preferably 100,000 or less, especially more preferably 50,000 or less.

In the present invention, the compatibilizer (D1) preferably contains at least any of the above-exemplified alkylene oxide copolymers, and may contain any other than the alkylene oxide copolymers, but preferably, all the copolymers contained are the above-exemplified alkylene oxide copolymers.

The ethylene oxide-propylene oxide copolymers can be prepared according to known methods. For example, regarding the ethylene oxide-propylene oxide-ethylene oxide triblock copolymer, the block copolymer having a propylene oxide chain as the main chain and an ethylene oxide chain at both ends thereof can be prepared by blowing ethylene oxide into propylene glycol under pressure and heat in the presence of an alkali catalyst to polymerize them to give a polypropylene oxide, and then polymerizing ethylene oxide at both ends that are polymerization sites of the polypropylene oxide, for example, in the presence of a metal alcoholate catalyst.

The content of the compatibilizer (D1) in the water-based temporary fixing adhesive is, from the viewpoint of improving cissing prevention performance along with temporary fixing performance and coating performance, preferably 0.1% by mass or more, more preferably 0.3% by mass or more, even more preferably 0.5% by mass or more, and the upper limit is preferably 20% by mass or less, more preferably 15% by mass or less, even more preferably 10% by mass or less.

### (Various Properties of First Water-Based Temporary Fixing Adhesive)

Regarding the properties of the first water-based temporary fixing adhesive, the melting point is preferably 30° C. or higher. When the above-mentioned component (A), component (B), component (C1) and component (D1) are combined and when the melting point is 30° C. or higher, reduction in coating performance to be caused by the compatibility resulting from difference in materials and surface properties between the temporary fixing adhesive and the adherend can be prevented more efficiently, and heat resistance against heating in mechanical processing can improve, and accordingly, occurrence of misalignment and peeling of the adherend from the support in processing can be prevented to attain more excellent temporary fixing performance (especially adhesion performance) and also attain general versatility that can accommodate temporary fixing of various adherends.

The preferred range of the melting point of the first water-based temporary fixing adhesive is the same as the preferred range of the melting point of the above-mentioned water-based temporary fixing adhesive.

### <Second Water-Based Temporary Fixing Adhesive>

The second water-based temporary fixing adhesive is characterized in that, in addition to the hydroxy group-having thermoplastic resin (A) and the glucide (B) mentioned above, the total content of a sodium metal ion, an aluminum metal ion, an iron metal ion, a zinc metal ion, a copper metal ion, a nickel metal ion, a chromium metal ion and a lead metal ion (these metal ions may be collectively referred to as “(C2) various metal ions”) is 3000 ppb or less, and the content of the sodium metal ion, the iron metal ion, the zinc metal ion and the copper metal ion is each individually 1000 ppb or less.

### ((C2) Various Metal Ions)

The second water-based temporary fixing adhesive is further such that the total content of a sodium metal ion, an aluminum metal ion, an iron metal ion, a zinc metal ion, a copper metal ion, a nickel metal ion, a chromium metal ion and a lead metal ion (hereinafter this may be simply referred to as “component (C2)”) is 3000 ppb or less, and the content of the sodium metal ion, the iron metal ion, the zinc metal ion and the copper metal ion is each individually 1000 ppb or less. In this description, “ppb” means “ppb by mass” unless otherwise specifically noted.

When the total content of various metal ions (C2) is larger than 3000 ppb, reliability of members may often worsen, for example, there may occur a problem of pn junction leakage owing to degradation of characteristics of members such as silicon wafers, and in addition, the production yield may increase abruptly. The same shall apply to the case where the content of a sodium metal ion, an iron metal ion, a zinc metal ion and a copper metal ion is each individually more than 1000 ppb.

In the second water-based temporary fixing adhesive, the content of various metal ions (C2) is preferably as small as possible, and is preferably 2500 ppb or less, more preferably 2000 ppb or less, even more preferably 1000 ppb or less, further more preferably 500 ppb or less, especially more preferably 200 ppb or less, and most preferably 100 ppb or less, from the viewpoint of more improving functional decline prevention performance of various members and parts for use in optical devices and electronic devices, that is, from the viewpoint of more efficiently preventing functional decline of various members and parts. The lower limit of the content of various metal ions (C2) is preferably 0 ppb, that is, it is preferable that various metal ions are not contained, but the reality is that the content is generally about 0.5 ppb or more.

The content of the sodium metal ion, the iron metal ion, the zinc metal ion and the copper metal ion is each individually preferably 950 ppb or less, more preferably 750 ppb or less, even more preferably 600 ppb or less, especially preferably 450 ppb or less, and the lower limit is preferably 0 ppb, but the reality is that the content is generally 0.5 ppb or more. In the second water-based temporary fixing adhesive, the content of various metal ions (C2) is a found value in measurement according to a suitable analysis method depending on the kind of each metal ion, and specifically, this is a found value in measurement according to the method described in the section of Examples.

In the second water-based temporary fixing adhesive, the content of various metal ions (C2) can be reduced, for example, by selecting the kind of the hydroxy group-having thermoplastic resin (A). As a resin component for use in an adhesive having temporary fixing performance, there may be employed salt-type ones using a metal salt of a resin such as a sodium salt of a resin such as an acrylic resin, and emulsion-type ones containing an emulsion of an acrylic resin or a vinyl acetate resin. However, the resin component used in such salt-type ones and emulsion-type ones may contain a metal ion by itself, or metal ions may be contained in raw materials for these resin components, or the resin components may be contaminated with such metal ions in the production process, and owing to these reasons, the content of the contaminants such as metal ions tends to be large in such resin components. In a metal-type resin component, the content of various metal ions (C2) contained therein is extremely high, while in an emulsion-type resin component, various metal ions (C2) are incorporated in the particles of the emulsion, and for these reasons, it is difficult to remove various metal ions from the resin components of these types.

Apart from the above-mentioned resin components, for example, thermoplastic resins having a sulfonic acid group (—SO₃H) or a carboxy group (—COOH) may be employed, but as compared with these resins, the hydroxy group-having thermoplastic resin (A) has higher affinity with water and therefore can secure stability as a water-based temporary fixing adhesive. In the second water-based temporary fixing adhesive, the hydroxy group-having thermoplastic resin (A) is used, and in this, therefore, the content of various metal ions (C2) can be readily reduced by the treatment for removing various metal ions (C2) to be mentioned below, and accordingly, the content of various metal ions (C2) in the adhesive can be extremely small.

### (Other Component: (D2) Surface Conditioner)

The second water-based temporary fixing adhesive preferably contains (D2) a surface conditioner as another component than the above-mentioned hydroxy group-having thermoplastic resin (A), glucide (B) and various metal ions (C2). The surface conditioner (D2) is a component improving mainly the coating performance of the adhesive, especially the coating performance for various electronic members such as wafers. In the case where an adhesive is applied to various members and parts for use for optical devices and electronic devices, the adhesive could not be applied up to the outer peripheries of various members and parts owing to difference in the materials between the adhesive and various members and parts, and could not be applied to the entire surfaces thereof. In such a case, when the surface conditioner (D2) is used along with the hydroxy group-having thermoplastic resin (A), excellent coating performance can be attained irrespective of the difference in the materials between the adhesive and various members and parts.

Not specifically limited, the surface conditioner (D2) may be any one having performance of solving the defects of coating films generally to be caused by viscosity change owing to molecular weight increase, surface tension change or formation of bubbles, such as those called a surface conditioner, a leveling agent, a wetting agent and an antifoaming agent. Preferred examples thereof include various surface conditioners, leveling agents, wetting agents and antifoaming agents such as acrylic, vinylic, silicone-based, fluorine-based, cellulosic, natural wax-based or water-soluble organic solvents, and also surfactants. Above all, nonionic surfactants are preferred.

Regarding nonionic surfactants, acetylene bond-having acetylene-based surfactants such as acetylene alcohol-based surfactants and acetylene glycol-based surfactants, fluorine-based surfactants and acrylic surface conditioners that are used as the surface conditioner (D2), examples thereof may be the same as those exemplified hereinabove for the surface conditioner (C1) in the first water-based temporary fixing adhesive.

As the surface conditioner (D2), from the viewpoint of improving temporary fixing performance and also coating performance, preferred are surface conditioners such as acetylene bond-having acetylene-based surfactants, e.g., acetylene alcohol-based surfactants and acetylene glycol-based surfactants, and fluorine-based surfactants and acrylic surface conditioners, more preferred are acetylene-based surfactants, fluorine-based surfactants and acrylic surface conditioners, an even more preferred are acetylene-based surfactants. From the viewpoint of removing metals, nonionic surfactants are preferred.

In the second water-based temporary fixing adhesive, the surface conditioner (D2) preferably contains at least any of the above-mentioned surface conditioners, and may contain any other than those exemplified in the above, but preferably, all the surface conditioners contained are the above-exemplified surface conditioners.

The content of the surface conditioner (D2) in the second water-based temporary fixing adhesive is, from the viewpoint of improving temporary fixing performance and also coating performance, preferably 0.01% by mass or more, more preferably 0.03% by mass or more, even more preferably 0.05% by mass or more, especially preferably 0.10% by mass or more, and the upper limit is preferably 5% by mass or less, more preferably 3% by mass or less, even more preferably 1.5% by mass or less, especially more preferably 1% by mass or less.

### (Other Component: (E2) Compatibilizer)

The second water-based temporary fixing adhesive preferably contains (E2) a compatibilizer as another component (hereinafter this may be referred to as “component (E2)”). The compatibilizer (E2) is a component which, when the above-mentioned surface conditioner (D2) is used, improves mainly the compatibility between the above-mentioned, hydroxy group-having thermoplastic resin (A) and the surface conditioner (D2) to express cissing prevention performance. The hydroxy group-having thermoplastic resin (A) contains a hydroxy group and is therefore hydrophilic, while on the other hand, the surface conditioner (D2) tends to be hydrophobic, and therefore, it cannot be said that the compatibility between the component (A) and the component (D2) is high. Consequently, when the component (A) and the component (D2) are used together, a part of the coating film of the adhesive may be a cissing part having a small coating amount of the adhesive or not coated with the adhesive, and if so, the adhesive could hardly be uniformly applied to various members or parts such as wafers. In the case where the surface conditioner (D2) is used for the hydroxy group-having thermoplastic resin (A), the compatibilizer (E2) used together with them can reduce cissing occurrence, and accordingly, the second water-based temporary fixing adhesive can have excellent temporary fixing performance and also functional decline prevention performance for various members and parts for use in optical devices and electronic devices, as well as excellent coating performance, adhesion-stain prevention performance and cissing prevention performance.

The compatibilizer (E2) for use in the second water-based temporary fixing adhesive is the same as the compatibilizer (D1) for use in the above-mentioned, first water-based temporary fixing adhesive, and is preferably an alkylene oxide copolymer. Specific examples of the alkylene oxide copolymer are the same as those of the compatibilizer (D1) for use in the first water-based temporary fixing adhesive. In the copolymer of the type, the ethylene oxide chain is hydrophilic while the propylene oxide chain is hydrophobic, and therefore the copolymer can more remarkably express compatibilization performance to improve the compatibility between the hydrophilic component (A) and the hydrophobic component (D2), and can attain more excellent cissing prevention performance. In addition, the alkylene oxide copolymer of the type does not contain a metal ion by itself, the raw materials of the copolymer do not contain a metal ion or the resultant copolymer is not contaminated with any metal ion in the production process, and for these reasons, the copolymer of the type is effective for improving functional decline prevention performance for various members and parts for use in optical devices and electronic devices.

Regarding commercial products of the alkylene oxide copolymer such as the ethylene oxide-propylene oxide-ethylene oxide triblock copolymer and the propylene oxide-ethylene oxide-propylene oxide triblock copolymer mentioned above, the same commercial products as those exemplified hereinabove for the first water-based temporary fixing adhesive are employable.

Regarding the ratio of ethylene oxide to propylene oxide in the ethylene oxide-propylene oxide copolymer, the number-average molecular weight of the alkylene oxide copolymer for the compatibilizer (E2), and the preparation method for the ethylene oxide-propylene oxide copolymer in a known manner, the contents thereof are the same as those described hereinabove for the first water-based temporary fixing adhesive.

The content of the compatibilizer (E2) in the second water-based temporary fixing adhesive is, from the viewpoint of improving temporary fixing performance and also coating performance and cissing prevention performance, preferably 0.1% by mass or more, more preferably 0.3% by mass or more, even more preferably 0.5% by mass or more, and the upper limit is preferably 20% by mass or less, more preferably 15% by mass or less, even more preferably 10% by mass or less.

### (Various Properties of Second Water-Based Temporary Fixing Adhesive)

The melting point of the second water-based temporary fixing adhesive is preferably 30° C. or higher. When the melting point is 30° C. or higher, reduction in coating performance to be caused by the compatibility resulting from difference in materials and surface properties between the temporary fixing adhesive and the adherend can be prevented, and heat resistance against heating in mechanical processing can improve, and accordingly, occurrence of misalignment and peeling of the adherend from the support in processing can be prevented to attain excellent temporary fixing performance (especially adhesion performance) and also attain general versatility that can accommodate temporary fixing of various adherends.

The preferred range of the melting point of the second water-based temporary fixing adhesive is the same as the preferred range of the melting point of the above-mentioned water-based temporary fixing adhesive.

### [Production Method for Second Water-Based Temporary Fixing Adhesive]

A production method for the second water-based temporary fixing adhesive includes contacting a composition containing a hydroxy group-having thermoplastic resin (A) and metal ions with an ion exchanger to make the total content of the sodium metal ion, the aluminum metal ion, the iron metal ion, the zinc metal ion, the copper metal ion, the nickel metal ion, the chromium metal ion and the lead metal ion be 3000 ppb or less and to make the content of the sodium metal ion, the iron metal ion, the zinc metal ion and the copper metal ion be individually 1000 ppm or less.

### (Ion Exchanger)

Examples of the ion exchanger for use for the production method for the second water-based temporary fixing adhesive include an organic ion exchanger such as an ion-exchange resin, and an inorganic ion exchanger. From the viewpoint of more efficiently reducing the content of various metal ions (C2), an organic ion exchanger such as an ion-exchange resin is preferred, and those having cation trapping performance are preferred.

Examples of the inorganic ion exchanger having cation trapping performance include metal oxides such as zirconium phosphate, zirconium tungstate, zirconium molybdate, zirconium tungstate, zirconium antimonite, zirconium selenite, zirconium tellurite, zirconium silicate, zirconium phosphosilicate, and zirconium polyphosphate. One alone or plural kinds of these inorganic ion exchangers can be used either singly or as combined.

The organic ion exchanger preferably uses a cation-exchange resin having cation trapping performance.

The cation-exchange resin for use herein may be any of a strong acidic cation-exchange resin such as a sulfonic acid-type strong acidic cation-exchange resin having a sulfonic acid group (RSO₃⁻H⁺) as an acid group; or a weakly acidic cation-exchange resin having a carboxyl acid group (R—COO⁻H⁺), a phosphonic acid group (R—P(O)(O⁻H⁺)₂) or a phosphinic acid group (R—PH(O)(O⁻H⁺)) as an acid group. Regarding the ion type of the cation-exchange resin, a hydrogen-type or an ammonia-type one is preferred, and from the viewpoint of more efficiently reducing the content of various metal ions (C2), a hydrogen-type cation-exchange resin is more preferred. One alone or plural kinds of these organic ion exchangers can be used either singly or as combined.

The form of the organic ion exchanger is not specifically limited, and any of granular, fibrous, liquid or gelatinous ones are usable. In addition, for example, those produced by modifying resin fibers of an acrylic resin or a styrenic resin with an organic ion-exchange resin are also usable.

Regarding the hydroxy group-having thermoplastic resin (A), the glucide (B), various metal ions (C2), and other optional components of the surface conditioner (D) and the compatibilizers and the content thereof, as well as other additives to be in the second water-based temporary fixing adhesive, the description for these is the same as that for the constituent components in the above-mentioned, second water-based temporary fixing adhesive, and is therefore omitted here.

The production method for the second water-based temporary fixing adhesive is not specifically limited, but the water-based temporary fixing adhesive is preferably produced according to the above-mentioned production method for the second water-based temporary fixing adhesive. According to the production method for the second water-based temporary fixing adhesive, the water-based temporary fixing adhesive having excellent temporary fixing performance and also having functional decline prevention performance for various members and parts for use for optical devices and electronic devices can be obtained with ease. The second water-based temporary fixing adhesive can also be produced by selecting the hydroxy group-having thermoplastic resin (A) that is contained in the adhesive and controlling the content of the metal ions therein to be on a predetermined level. The present production method is described as a production method for the second water-based temporary fixing adhesive, but in producing the above-mentioned, first water-based temporary fixing adhesive and also the third water-based temporary fixing adhesive to be mentioned hereinunder where a composition containing a hydroxy group-having resin (A) and metal ions is used, the adhesives can also be produced using an ion exchanger according to the present production method.

### <Third Water-Based Temporary Fixing Adhesive>

The third water-based temporary fixing adhesive is characterized by further containing, in addition to the above-mentioned, hydroxy group-having thermoplastic resin (A) and glucide (B), a water-containing solvent (C3) in which the content of water in the solvent is 95% by mass or more, and having a surface tension at 25° C. of 20 mN/m or more and 55 mN/m or less and an adhesion strength of 0.1 MPa or more and 20 MPa or less.

Further containing a water-containing solvent (C3), and having a surface tension at 25° C. of 20 mN/m or more and 55 mN/m or less and an adhesion strength of 0.1 MPa or more and 20 MPa or less, the third water-based temporary fixing adhesive can have more improved temporary fixing performance and coating performance, and in addition, since the adhesive is a water-based one in which the content of water in the solvent is 95% by mass or more, it secures high safety and low load on the environment.

### ((C3) Water-Containing Solvent)

The third water-based temporary fixing adhesive contains a water-containing solvent (hereinafter this may be referred to as “component (C3)”), in which the content of water in the solvent is 95% by mass or more.

Water for use in the water-containing solvent (C3) may be, for example, ion-exchanged water. The third water-based temporary fixing adhesive may contain any other solvent than water of, for example, various organic solvents, but in consideration of reducing the load on the environment such as natural environments and working environments and securing safety, the content of an organic solvent is preferably as small as possible. The water content in the water-containing solvent (C3) needs to be 95% by mass or more. By reducing the content of any other solvent than water in such a manner, the adhesive can secure excellent safety performance and can reduce the load on the environment.

From the same viewpoint, the water content in the water-containing solvent (C3) is preferably 96% by mass or more, more preferably 98% by mass or more, and even more preferably, the adhesive is a substantially completely water-based temporary fixing adhesive not containing an organic solvent.

Here, “not containing an organic solvent” means that the content of an organic solvent is 0% by weight and, in addition thereto, the adhesive does not intentionally contain an organic solvent. For example, it means that presence of an organic solvent that is inevitably contained in the above-mentioned component (A) and component (B) and in a component (D3) and a component (E3) to be mentioned below is accepted, and in that case, the content of the organic solvent contained in all the solvents is preferably 1% by mass or less, more preferably 0.5% by mass or less, eve more preferably 0.1% by mass or less. Specifically in the present invention, “not containing an organic solvent” means that the water content in all the solvents is preferably 99% by mass or more, more preferably 99.5% by mass or more, even more preferably 99.9% by mass or more.

The content of the water-containing solvent (C3) in the third water-based temporary fixing adhesive can be appropriately changed depending on the content of the above-mentioned component (A) and component (B) and the other components to be mentioned below, but is generally approximately 50% by mass or more and 95% by mass or less.

### (Other Component: (D3) Surface Conditioner)

The third water-based temporary fixing adhesive preferably contains (D3) a surface conditioner as another component than the above-mentioned hydroxy group-having thermoplastic resin (A), glucide (B) and water-containing solvent (C3). The surface conditioner (D3) is a component improving mainly the coating performance of the adhesive, especially the coating performance for various electronic members such as wafers. In the case where an adhesive is applied to various members and parts for use for optical devices and electronic devices, the adhesive could not be applied up to the outer peripheries of various members and parts owing to difference in the materials between the adhesive and various members and parts, and could not be applied to the entire surfaces thereof. In such a case, when the surface conditioner (D3) is used along with the hydroxy group-having thermoplastic resin (A), the surface tension of the third water-based temporary fixing adhesive can be controlled, and excellent coating performance can be attained irrespective of the difference in the materials between the adhesive and various members and parts.

Not specifically limited, the surface conditioner (D3) may be any one having performance of solving the defects of coating films generally to be caused by viscosity change owing to molecular weight increase, surface tension change or formation of bubbles, such as those called a surface conditioner, a leveling agent, a wetting agent and an antifoaming agent. Preferred examples thereof include various surface conditioners, leveling agents, wetting agents and antifoaming agents such as acrylic, vinylic, silicone-based, fluorine-based, cellulosic, natural wax-based or water-soluble organic solvents, and also surfactants. Also as the surface conditioner (D3), surfactants are preferred, and nonionic surfactants are preferred.

Regarding nonionic surfactants, acetylene bond-having acetylene-based surfactants such as acetylene alcohol-based surfactants and acetylene glycol-based surfactants, fluorine-based surfactants and acrylic surface conditioners that are used as the surface conditioner (D3), examples thereof may be the same as those exemplified hereinabove for the surface conditioner (C3) in the first water-based temporary fixing adhesive.

As the surface conditioner (D3), from the viewpoint of improving temporary fixing performance and coating performance and also cissing prevention performance, preferred are surface conditioners such as acetylene bond-having acetylene-based surfactants, e.g., acetylene alcohol-based surfactants and acetylene glycol-based surfactants, and fluorine-based surfactants and acrylic surface conditioners, more preferred are acetylene-based surfactants, fluorine-based surfactants and acrylic surface conditioners, an even more preferred are acetylene-based surfactants. Fluorine-based surfactants include both nonionic ones and ampholytic ones, but from the viewpoint of improving temporary fixing performance and also coating performance and cissing prevention performance, nonionic surfactants are preferred.

In the third water-based temporary fixing adhesive, the surface conditioner (D3) preferably contains at least any of the above-mentioned surface conditioners, and may contain any other than those exemplified in the above, but preferably, all the surface conditioners contained are the above-exemplified surface conditioners.

The content of the surface conditioner (D3) in the third water-based temporary fixing adhesive is, from the viewpoint of improving temporary fixing performance and also functional decline prevention performance for various parts for optical devices and electronic devices as well as coating performance, preferably 0.01% by mass or more, more preferably 0.03% by mass or more, even more preferably 0.05% by mass or more, especially preferably 0.10% by mass or more, and the upper limit is preferably 5% by mass or less, more preferably 3% by mass or less, even more preferably 1.5% by mass or less, especially more preferably 1% by mass or less.

### (Other Component: (E3) Compatibilizer)

The third water-based temporary fixing adhesive preferably contains (E3) a compatibilizer as another component (hereinafter this may be referred to as “component (E3)”). Regarding the compatibilizer (E3), in the case where the surface conditioner (D3) is used, even when the third water-based temporary fixing adhesive could be applied up to the outer peripheries of various members, there may occur so-called cissing that means failure in uniform coating owing to cissing to occur partly. In the case of occurrence of cissing, when the compatibilizer (E3) is used, the compatibility between the hydroxy group-having thermoplastic resin (A) and the surface conditioner (D3) can be improved so as to improve cissing prevention performance.

The hydroxy group-having thermoplastic resin (A) contains a hydroxy group and is therefore hydrophilic, while on the other hand, the surface conditioner (D3) tends to be hydrophobic, and therefore, it cannot be said that the compatibility between the component (A) and the component (D3) is high. Consequently, when the component (A) and the component (D3) are used together, a part of the coating film of the adhesive may be a cissing part having a small coating amount of the adhesive or not coated with the adhesive, and if so, the adhesive could hardly be uniformly applied to various members or parts such as wafers. In the case where the surface conditioner (D3) is used for the hydroxy group-having thermoplastic resin (A), the compatibilizer (E3) used together with them can reduce cissing occurrence, and accordingly, the third water-based temporary fixing adhesive can have excellent temporary fixing performance and coating performance and also cissing prevention performance.

The compatibilizer (E3) for use in the third water-based temporary fixing adhesive is the same as the compatibilizer (D1) for use in the above-mentioned, first water-based temporary fixing adhesive, and is preferably an alkylene oxide copolymer. Specific examples of the alkylene oxide copolymer are the same as those of the compatibilizer (D1) for use in the first water-based temporary fixing adhesive. In the copolymer of the type, the ethylene oxide chain is hydrophilic while the propylene oxide chain is hydrophobic, and therefore the copolymer can more remarkably express compatibilization performance to improve the compatibility between the hydrophilic component (A) and the hydrophobic component (D3), and can attain more excellent cissing prevention performance.

Regarding commercial products of the alkylene oxide copolymer such as the ethylene oxide-propylene oxide-ethylene oxide triblock copolymer and the propylene oxide-ethylene oxide-propylene oxide triblock copolymer mentioned above, the same commercial products as those exemplified hereinabove for the first water-based temporary fixing adhesive are employable.

Regarding the ratio of ethylene oxide to propylene oxide in the ethylene oxide-propylene oxide copolymer, the number-average molecular weight of the alkylene oxide copolymer for the compatibilizer (E3), and the preparation method for the ethylene oxide-propylene oxide copolymer in a known manner, the contents thereof are the same as those described hereinabove for the first water-based temporary fixing adhesive.

The content of the compatibilizer (E3) in the third water-based temporary fixing adhesive is, from the viewpoint of improving temporary fixing performance and also coating performance and cissing prevention performance, preferably 0.1% by mass or more, more preferably 0.3% by mass or more, even more preferably 0.5% by mass or more, and the upper limit is preferably 20% by mass or less, more preferably 15% by mass or less, even more preferably 10% by mass or less.

### (Various Properties of Water-Based Temporary Fixing Adhesive)

The surface tension at 25° C. of the third water-based temporary fixing adhesive needs to be 20 mN/m or more and 55 mN/m or less. When the surface tension at 25° C. does not fall within the above range, the adhesive cannot have excellent temporary fixation performance and coating performance. From the viewpoint of improving both temporary fixing performance and coating performance, the surface tension at 25° C. of the third water-based temporary fixing adhesive is preferably 20 mN/m or more, more preferably 22 mM/m or more, even more preferably 25 mN/m or more, and the upper limit is preferably 55 mN/m or less, more preferably 50 mN/m or less, even more preferably 45 mN/m or less. In the present invention, the surface tension at 25° C. can be controlled by the kind of the hydroxy group-having thermoplastic resin (A) and the content thereof, and can also be controlled by using the surface conditioner (D3).

In this description, the surface tension at 25° C. is a value measured according to the Wolhelmy method at a measurement temperature of 25° C., and is, for example, a value that can be measured using a surface tensiometer (“CBVP-Z (Model Code)”, by Kyowa Interface Science Co., Ltd.).

The adhesion strength of the third water-based temporary fixing adhesive needs to be 0.1 MPa or more and 20 MPa or less. When the adhesion strength does not fall within the above range, the adhesive cannot have excellent temporary fixing performance. From the viewpoint of improving temporary fixing performance, the adhesion strength of the third water-based temporary fixing adhesive is preferably 0.15 MPa or more, more preferably 0.2 MPa or more, even more preferably 0.5 MPa or more, and the upper limit is preferably 15 MPa or less, more preferably 10 MPa or less, even more preferably 7 MPa or less, further more preferably 5 MPa or less.

In this description, the adhesion strength is a shear force measured according to “Test Method for Tensile Shear Adhesion Strength” defined in JIS K6850:1999, in which 5 drops of the adhesive to be tested are applied to one stainless substrate, dried under heat at 100° C. for 20 minutes, and then another stainless substrate is stuck thereto, cooled to room temperature, and after 20 minutes, the shear force of the bonded substrates is measured using a tensile strength measuring device.

### (Use of Water-Based Temporary Fixing Adhesive)

The water-based temporary fixing adhesive of the present invention has excellent temporary fixing performance, coating performance and adhesion-stain prevention performance and is a water-based one, and therefore can reduce the load on the environment such as natural environments and working environments to be an adhesive excellent also in safety. Consequently, the water-based temporary fixing adhesive of the present invention is favorably used for applications that require temporary fixing performance of adhesives, for example, in temporary fixation on supports (temporary fixation) in various mechanical processing such as machining, polishing, cutting, grinding or drilling of various members and parts for use in various electronic devices such as OA devices, information devices and home electric appliances, as well as in other various devices such as optical devices, medical devices and automobile devices, for example, wafers such as silicon wafers, or optical lenses, sapphire, gallium arsenic, quartz, magnetic members, metal members, glass members, resin members or members for semiconductor devices.

The water-based temporary fixing adhesive of the present invention exhibits adhesion performance to prevent various members and parts from being peeled or misaligned from processing substrates (e.g., surface plates) in mechanical processing, and after polishing processing, various members and parts can be readily peeled from the processing substrates (e.g., surface plates) by using razor or by heating and melting. The water-based temporary fixing adhesive of the present invention is excellent in coating performance and adhesion-stain prevention performance, and the coating film of the adhesive can uniformly exist on the entire surfaces of various members and parts, and therefore, the water-based temporary fixing adhesive of the present invention can satisfy even high-accuracy performance requirements, for example, in mechanical processing. Consequently, the second water-based temporary fixing adhesive is favorably used for machine processing that requires especially high accuracy, for example, for polishing processing of wafers such as silicon wafers, optical lenses or members for semiconductor devices, especially for polishing processing of surfaces of wafers such as silicon wafers.

### [Production Method for Members or Parts]

The production method for members or parts of the present invention includes a temporary fixing step of temporarily fixing a precursor of a member or a part and a processing substrate using the water-based temporary fixing adhesive of the present invention, and a processing step of mechanically processing the precursor to form a member or a part. Hereinunder the temporary fixing step and the processing step are described in detail.

The temporary fixing step is a step of temporarily fixing a precursor of a member or a part and a processing substrate using the water-based temporary fixing adhesive of the present invention, and more specifically, this is a step of forming a coating film of the water-based temporary fixing adhesive of the present invention between the precursor and the processing substrate to temporarily fix precursor and the processing substrate. The method of forming a coating film for temporary fixation may be any of (i) a method of applying the temporary fixing adhesive on one surface of the substrate to form a coating film thereon, and the precursor is temporarily fixed to the processing substrate via the coating film-formed surface thereof serving as a sticking surface, or (ii) a method of applying the temporary fixing adhesive on the substrate to form a coating film thereon, and arranging the precursor on the coating film to thereby temporarily fix the precursor on the processing substrate via the coating film.

For example, the method (i) is a coating method with the water-based temporary fixing adhesive, including a spin coating method, a spraying method, a die coating method, an inkjet method, a clip coating method and a roll coating method. The coating amount of the water-based temporary fixing adhesive is, though depending on the area of the surface to be temporarily fixed of the substrate, for example, approximately 1 to 3 mL for a precursor of a wafer member such as a 4-inch silicon wafer.

Subsequently, a processing substrate is made to face the coating film formed on the precursor, and the precursor is arranged in a predetermined position of the processing substrate, and temporarily fixed thereto. At that time, the precursor and the processing substrate are compressed under heat generally at a temperature of 50 to 140° C. for temporary fixation. In that manner, temporary fixation can be more surely attained and is favorable.

Before temporarily fixed to the processing substrate, the surface of the precursor may be roughly polished with an abrasive and may be optionally surface-treated by chemical etching.

The processing step is a step of processing the surface to be processed of the precursor that has been temporarily fixed to the processing substrate in the temporary fixing step. Processing in the production method of the present invention includes various mechanical processes of machining, polishing, cutting, grinding and drilling, and may be a single processing of any of these, or a combined processing thereof.

Processing in the processing step in the production method of the present invention is roughly classified into general processing in which no particular precision is required and precision processing in which high precision is required. For example, mechanical processing of wafers such as silicon wafers, optical lenses and members for semiconductor devices, especially polishing processing of surfaces of wafers such as silicon wafers requires precision processing. In the production method of the present invention, the water-based temporary fixing adhesive of the present invention having excellent temporary fixation performance is used, and therefore a precursor can be temporarily fixed to a processing substrate with no inclination, and the in-plane film thickness difference of the coating film of the adhesive is small, and additionally a non-coated area is extremely small. Consequently, in the processing step, the pressure applied to the surface to be processed of the precursor from the mechanically processing tool can be almost uniform relative to the surface to be processed of the precursor, and as a result, the precursor can be processed with a high degree of accuracy to give high-quality members or parts.

According to the production method of the present invention, high-accuracy processing is possible even under severe mechanical processing conditions, and wafers processable according to the method include, in addition to silicon wafers, various wafers of wafer materials such as sapphire, gallium phosphide and gallium nitride. For the production method for these various wafers, in particular, also preferred is a production method for a wafer having a Mohs hardness of 9 or more (e.g., sapphire wafer).

The production method for members or parts of the present invention may have a peeling step of peeling the mechanically-processed member or part from the processing substrate, after the above-mentioned processing step. Regarding peeling, the member or part such as a wafer may be peeled from the processing substrate, for example, by using a razor or a scraper, or by heating and melting.

Also if desired, after the member or the part has been peeled, a residue of the temporary fixing adhesive remaining on the member of the part may be removed by washing away with water or hot water. As a water-based one, the water-based temporary fixing adhesive of the present invention has another advantage that it can be readily removed from adherends by washing with water or warm water.

Examples of the members and the parts obtained according to the production method for members or parts of the present invention include various members and parts for use in various electronic devices such as OA devices, information devices and home electric appliances, as well as in other various devices such as optical devices, medical devices and automobile devices, more specifically wafers such as silicon wafers, or optical lenses, sapphire, gallium arsenic, quartz, magnetic members, metal members, glass members, resin members and members for semiconductor devices. In consideration of the characteristic features of the production method for members or parts of the present invention, the production method is favorable for various wafers such as silicon wafers and, in addition thereto, those of wafer materials such as sapphire, gallium phosphide and gallium nitride, as well as optical lenses and members for semiconductor devices, and is especially favorable for various wafers.

### EXAMPLES

Next, the present invention is described in detail by Examples, but the present invention is not whatsoever restricted by these Examples.

### (Evaluation and Measurement Methods: First Water-Based Temporary Fixing Adhesive)

### (1-1) Measurement of Melting Point

The melting point of the adhesive obtained in Examples and Comparative Examples was measured according to JIS K0064:1992. Specifically, a sample dried by removing water from the adhesive obtained in Examples and Comparative Examples (a sample prepared by putting 2 ml of the adhesive in a small-size Petri dish having an inner diameter of 40 mm, and with no lid, drying it in a clean oven under the condition of 120° C. and 60 minutes) and A-PEG 1 to 7 and A-PPGS used in these Examples each were melted by heating (temperature condition: 30 to 90° C.), then cooled (temperature condition: −20 to 30° C.) and thereafter ground into fine powder (maximum particle size: 300 μm), and the resultant powder was filled in a capillary (made of glass, inner diameter: 0.8 to 1.2 mm, thickness: 0.2 to 0.3 mm, length; 150 mm), and heated at a heating speed of 1° C./min. The melting temperature at which any solid could no more be recognized in visual observation (the temperature at which the powdery solid sample completely liquefied) is referred to as the melting point of the adhesive.

### (2-1) Evaluation of Adhesion Performance

Five drops of the adhesive obtained in Examples and Comparative Examples were applied to one stainless substrate, dried under heat at 100° C. for 20 minutes, and then another stainless substrate was stuck thereto, cooled to room temperature, and after 20 minutes, the shear force of the bonded substrates was measured using a tensile strength measuring device according to “Test Method for Tensile Shear Adhesion Strength” defined in JIS K6850:1999, and evaluated based on the following criteria. In the Examples, those given an evaluation rank B or higher were regarded as acceptable.

A: The shear force was 0.5 MPa or more.

B: The shear force was 0.1 MPa or more and less than 0.5 MPa.

C: The shear force was less than 0.1 MPa.

### (3-1) Evaluation of Peel Performance

The adhesive obtained in Examples and Comparative Examples was applied onto one surface of a silicon wafer (size: φ150 mm, thickness: 625 μm) using a spin coater (rotation number: 3000 rpm, coating time: 3 seconds), and the silicon wafer was bonded to a ceramic surface plate by heating under pressure under the temperature condition of 70° C. Next, this was cooled down to room temperature for temporary fixation, a razor was fitted to a tool so that the edge thereof could be inclined by 15°, and the edge thereof was inserted between the silicon wafer and the surface plate. According to the inserted depth (mm), the tested sample was evaluated based on the following criteria. In the Examples, those given an evaluation rank B or higher were regarded as acceptable.

A: The silicon wafer was peeled from the surface plate when the inserted depth was less than 10 mm.

B: The silicon wafer was peeled from the surface plate when the inserted depth was 10 mm or more and less than 15 mm.

C: The silicon wafer was peeled from the surface plate when the inserted depth was 15 mm or more.

### (4-1) Evaluation of Coating Performance

The adhesive obtained in Examples and Comparative Examples was applied onto one surface of a silicon wafer (size: φ150 mm, thickness: 625 μm) using a spin coater (rotation number: 3000 rpm, coating time: 3 seconds), and the ratio of the coating film area of the adhesive to the entire area of the silicon wafer was visually observed, and evaluated based on the following criteria. In the Examples, those given an evaluation rank B or higher were regarded as acceptable.

A: The coating film area was 100%.

B: The coating film area was 80% or more and less than 100%.

C: The coating film area was less than 80%.

### (5-1) Evaluation of Adhesion-Stain Prevention Performance

The adhesive obtained in Examples and Comparative Examples was applied onto one surface of a silicon wafer (size: φ150 mm, thickness: 625 μm) using a spin coater (rotation number: 3000 rpm, coating time: 3 seconds), and the silicon wafer was bonded to a ceramic surface plate by heating under pressure under the temperature condition of 70° C. Next, this was cooled down to room temperature for temporary fixation, an end of a razor was inserted between the silicon wafer and the surface plate to peel them from each other. The condition of the surface of the coating film with the adhesive remaining on the silicon wafer was visually confirmed, and evaluated based on the following criteria. In the Examples, those given an evaluation rank B or higher were regarded as acceptable.

AA: The film thickness was uniform, and no adhesion stain was observed on the coated surface.

A: The film thickness in the outer circumference of 10 mm was uniform, and no adhesion stain was observed, or some adhesion stains were confirmed only outside the outer circumference of 10 mm but there was no practical problem.

B: The film thickness was almost uniform, or some adhesion stains were confirmed, but there was no practical problem.

C: The film thickness was not uniform, and adhesion stains were observed on the coated surface.

### (6-1) Evaluation of Cissing Prevention Performance

According to the same method as in the above (4-1), the adhesive obtained in Examples and Comparative Examples was applied onto one surface of a silicon wafer, and the ratio of the area of the cissing portion in the coating film with the adhesive to the entire area of the silicon wafer was visually observed, and evaluated based on the following criteria. In the Examples, those given an evaluation rank B or higher were regarded as acceptable.

A: The cissing area was 0%.

B: The cissing area was more than 0% and 10% or less.

C: The cissing area was more than 10%.

### Examples 1-1 to 14-1, Comparative Examples 1-1 to 3-1

Adhesives were prepared in the blending ratio (% by mass) shown in Table 1. According to the above-mentioned methods (1-1) to (6-1), the resultant adhesives were measured and evaluated in point of the melting point, temporary fixing performance (adhesion performance and peel performance), coating performance and cissing prevention performance. The evaluation results are shown in Table 1.

TABLE 1

| | | Example | | | | | | | | |
|---|---|---|---|---|---|---|---|---|---|---|
| | | 1-1 | 2-1 | 3-1 | 4-1 | 5-1 | 6-1 | 7-1 | 8-1 | 9-1 |
| (A) | A-PEG1 | 10.6 | 10.6 | 10.6 | 10.6 | 10.6 | — | — | — | — |
| | A-PEG2 | 10.6 | 10.6 | 10.6 | 10.6 | 10.6 | 10.6 | 10.6 | 10.6 | — |
| | A-PEG3 | — | — | — | — | — | 10.6 | 10.6 | 10.6 | — |
| | A-PEG4 | — | — | — | — | — | — | — | — | 21.2 |
| | A-PEG5 | — | — | — | — | — | — | — | — | — |
| (B) | B-1 | 4.0 | 4.0 | 4.0 | 1.0 | 8.0 | 4.0 | 1.0 | 8.0 | 4.0 |
| (C) | C-1 | 0.2 | — | — | 0.2 | 0.2 | 0.2 | 0.2 | 0.2 | 0.2 |
| | C-2 | — | 0.2 | — | — | — | — | — | — | — |
| | C-3 | — | — | 0.2 | — | — | — | — | — | — |
| (D) | D-1 | 1.0 | 1.0 | 1.0 | 1.0 | 1.0 | 1.0 | 1.0 | 1.0 | 1.0 |
| | D-2 | — | — | — | — | — | — | — | — | — |
| | D-3 | — | — | — | — | — | — | — | — | — |
| | Ion-exchanged Water | 73.6 | 73.6 | 73.6 | 76.6 | 69.6 | 73.6 | 76.6 | 69.6 | 73.6 |
| | Total | 100.0 | 100.0 | 100.0 | 100.0 | 100.0 | 100.0 | 100.0 | 100.0 | 100.0 |
| | Melting Point (° C.) | 47 | 47 | 47 | 47 | 47 | 58 | 58 | 58 | 46 |
| Evaluation | Adhesion Performance | A | B | A | A | A | A | A | A | A |
| | Peel Performance | A | A | A | A | A | A | A | A | A |
| | Coating Performance | A | A | B | A | A | A | A | A | A |
| | Adhesion-stain Prevention | AA | A | B | A | A | A | A | A | A |
| | Performance | | | | | | | | | |
| | Cissing Prevention | A | A | B | A | A | A | A | A | A |
| | Performance | | | | | | | | | |
| | | | Example | | | | | Comparative Example | | |
| | | | 10-1 | 11-1 | 12-1 | 13-1 | 14-1 | 1-1 | 2-1 | 3-1 |
| | (A) | A-PEG1 | — | — | — | — | — | — | — | 10.6 |
| | | A-PEG2 | — | — | — | — | — | — | — | 10.6 |
| | | A-PEG3 | — | — | — | — | — | — | — | — |
| | | A-PEG4 | 21.2 | 21.2 | — | — | — | — | — | — |
| | | A-PEG5 | — | — | 21.2 | 21.2 | 21.2 | — | — | — |
| | (B) | B-1 | 4.0 | 4.0 | 4.0 | 4.0 | 4.0 | — | 4.0 | — |
| | (C) | C-1 | 0.2 | 0.2 | 0.2 | 0.2 | 0.2 | 0.2 | 0.2 | 0.2 |
| | | C-2 | — | — | — | — | — | — | — | — |
| | | C-3 | — | — | — | — | — | — | — | — |
| | (D) | D-1 | — | — | 1.0 | — | — | 20.7 | 20.7 | 1.0 |
| | | D-2 | 1.0 | — | — | 1.0 | — | — | — | — |
| | | D-3 | — | 1.0 | — | — | 1.0 | — | — | — |
| | | Ion-exchanged | 73.6 | 73.6 | 73.6 | 73.6 | 73.6 | 79.1 | 75.1 | 77.6 |
| | | Water | | | | | | | | |
| | | Total | 100.0 | 100.0 | 100.0 | 100.0 | 100.0 | 100.0 | 100.0 | 100.0 |
| | | Melting Point (° C.) | 46 | 46 | 50 | 50 | 50 | 50 | 50 | 47 |
| | Evaluation | Adhesion | B | A | A | A | A | — | — | A |
| | | Performance | | | | | | | | |
| | | Peel Performance | A | A | A | A | A | — | — | A |
| | | Coating | A | A | A | A | A | C | — | A |
| | | Performance | | | | | | | | |
| | | Adhesion-stain | A | A | A | A | A | C | — | C |
| | | Prevention | | | | | | | | |
| | | Performance | | | | | | | | |
| | | Cissing Prevention | A | A | A | B | A | — | — | A |
| | | Performance | | | | | | | | |

Notes)
Details of the components used in these Examples and shown in Table 1 are as follows.
A-PEG1: Polyethylene glycol (number-average molecular weight: 1,000, melting point: 40° C.)
A-PEG2: Polyethylene glycol (number-average molecular weight: 3,100, melting point: 55° C.)
A-PEG3: Polyethylene glycol (number-average molecular weight: 8,800, melting point: 60° C.)
A-PEG4: Polyethylene glycol (number-average molecular weight: 1,540, melting point: 45° C.)
A-PEG5: Polyethylene glycol (number-average molecular weight: 2,000, melting point: 50° C.)
B-1: Mannitol
C-1: Acetylene glycol-based surfactant (2,4,7,9-tetramethyl-5-decyne-4,7-diol ethylene oxide adduct represented by the general formula (2) where R²¹ and R²³ are methyl groups, R²² and R²⁴ are isobutyl groups, and A₂₁ and A₂₂ are single bonds (oxyethylene group recurring unit number: 4))
C-2: Fluorine-based surfactant (partially fluorinated alcohol-substituted glycol, trade name “Capstone FS-34” by DuPont Corporation)
C-3: Acrylic surfactant (trade name “BYK-3440”, by BYK Japan KK)
D-1: Alkylene oxide block copolymer (copolymer represented by ethylene oxide-propylene oxide-ethylene oxide triblock copolymer (HO—(EO)ₐ—(PO)₅₅—(EO)_{b}—H (a + b = 300) (EO: ethylene oxide, PO: propylene oxide)), number average molecular weight: 16500, ethylene oxide/propylene oxide (molar ratio) = 300/55)
D-2: Alkylene oxide block copolymer (propylene oxide-ethylene oxide-propylene oxide triblock copolymer, produced by preparing a polyethylene glycol (number-average molecular weight: 12,000) through polymerization of 5.2 parts by mass of ethylene glycol with 995 parts by weight of ethylene oxide blown thereinto under pressure and under heat in the presence of an alkali catalyst, followed by polymerizing the polyethylene glycol with 1,000 parts by weight of propylene oxide using a metal alcoholate catalyst, where the main chain polyethylene glycol has polypropylene glycol at both ends thereof by 100% by mass partial addition polymerization)
D-3: Alkylene oxide block copolymer (copolymer represented by ethylene oxide-propylene oxide triblock copolymer (HO—(EO)ₐ—(PO)₃₅—(EO)_{b}—H (a + b = 150) (EO: ethylene oxide, PO: propylene oxide)), number-average molecular weight: 9,400, ethylene oxide/propylene oxide (molar ratio) = 150/35)

From the results in Examples, it is confirmed that the first water-based temporary fixing adhesive is excellent in temporary fixing performance satisfying both adhesion performance and peel performance, and in coating performance and adhesion-stain prevention performance and is also excellent in cissing prevention performance and, as a result, highly accurate silicon wafers were obtained. In addition, the adhesive of the present invention is a water-based adhesive not substantially containing an organic solvent, and therefore can reduce the load on the environment such as natural environments and working environments and is excellent in safety.

On the other hand, the adhesive of Comparative Example 1-1 not containing the component (A) and the component (B), and the adhesive of Comparative Example 2-1 not containing the component (A) did not exhibit adhesion performance. From comparison between Comparative Example 3-1 and Examples, it is confirmed that, by using the component (B), coating performance, especially adhesion-stain prevention performance is improved.

### (Evaluation and Measurement Methods: Second Water-Based Temporary Fixing Adhesive)

### (1-2) Measurement of Content of Various Metal Ions

The adhesive obtained in Examples and Comparative Examples was weighed in a platinum container, and ashed by heating in an electric furnace at a heating temperature of 550° C. This was processed with dilute hydrochloric acid and dissolved in dilute nitric acid to make the volume thereof constant. According to an atomic absorption analysis method using a polarized Zeeman atomic absorptiometer (“180-80 (Model Number)”, by Hitachi Limited), the resultant solution was analyzed to measure the content of the sodium metal ion therein; and using an ICP mass spectroscope (“SPQ6500 (Model Number)”, by Seiko Instruments Inc.) and according to an ICP mass spectrometry method, the content of the aluminum metal ion, the zinc metal ion, the nickel metal ion, and the chromium metal ion was measured; using a polarized Zeeman atomic absorptiometer (“Z8270 (Model Number)”, by Hitachi Limited) and according to frameless atomic absorptiometry method, the content of the copper metal ion was measured; and using a sequential ICP emission spectrophotometer (“SPS4000 (Model Number)”, by Seiko Instruments Inc.) and according to ICP emission spectrophotometry method, the content of the ion metal ion was measured.

The adhesive obtained in Examples and Comparative Examples was weighed in a Teflon (registered trademark) beaker, then decomposed under heat with sulfuric acid, nitric acid and perchloric acid, and dissolved in dilute nitric acid to make the volume thereof constant. According to an ICP mass spectrometry method using an ICP mass spectroscope (“SPQ6500 (Model Number)”, by Seiko Instruments Inc.), the content of the lead metal ion was measured. The found values of the content (ppb) of various metal ions are shown in Table 1-2.

### (2-2) Measurement of Melting Point

The melting point of the adhesive obtained in Examples and Comparative Examples was measured according to the same method of the above “(1-1) Measurement of melting point”.

### (3-2) Evaluation of Adhesion Performance

The adhesives were evaluated according to the same method and based on the same criteria as in the above “(2-1) Evaluation of adhesion performance”. In the Examples, those given an evaluation rank B or higher were regarded as acceptable.

### (4-2) Evaluation of Peel Performance

The adhesives were evaluated according to the same method and based on the same criteria as in the above “(3-1) Evaluation of peel performance”. In the Examples, those given an evaluation rank B or higher were regarded as acceptable.

### (5-2) Evaluation of Adhesion-Stain Prevention Performance

The adhesives were evaluated according to the same method and based on the same criteria as in the above “(5-1) Evaluation of adhesion-stain prevention performance”. In the Examples, those given an evaluation rank B or higher were regarded as acceptable.

### Examples 1-2 to 6-2, Comparative Examples 1-2 to 3-2

Adhesives were prepared in the blending ratio (% by mass) shown in Table 2, and the metal ions were removed according to the metal ion removal methods shown in Table 2 to give adhesives of Examples and Comparative Examples. The metal ion removal methods are as follows. The resultant adhesives were analyzed to measure the content of various metal ions according to the above-mentioned method (1-2), to measure the melting point according to the above-mentioned method (2-2), to evaluate the temporary fixing performance according to the above-mentioned methods (3-2) and (4-2), and to evaluate the adhesion-stain prevention performance according to the above-mentioned method (5-2). The evaluation results are shown in Table 2.

### (Metal Ion Removal Method)

A: Each adhesive was processed with an ion exchanger of a hydrogen-type cation-exchange resin (“Orlite DS-4 (Model Number)”, acid group: sulfonic acid group, by Organo Corporation) as an ion exchanger.

B: Each adhesive was processed with an ion exchanger of an ammonia-type cation-exchange resin (ammonia-type cation-exchange resin prepared by filling a resin column (diameter: 13 cm, height: 50 cm) with “Orlite DS-4 (Model Number)” by Organo Corporation), and flowing down 4 L of 10% aqueous ammonia through the column at a linear speed of 1 cm/min, and washing the resin with ion-exchanged water until the flowing liquid could be neutral).

-: Not processed for metal ion removal.

TABLE 2

| | | Example | | | | | | Comparative Example | | |
|---|---|---|---|---|---|---|---|---|---|---|
| | | 1-2 | 2-2 | 3-2 | 4-2 | 5-2 | 6-2 | 1-2 | 2-2 | 3-2 |
| Blending | A-PEG1 | 10.6 | 10.6 | 10.6 | — | — | — | — | — | 10.6 |
| Amount | A-PEG2 | 10.6 | 10.6 | 10.6 | 20.9 | 20.9 | 20.9 | — | — | 10.6 |
| | A-Salt | — | — | — | — | — | — | 20.4 | — | — |
| | A-Emulsion | — | — | — | — | — | — | — | 20.6 | — |
| | B-1 | 4.0 | 4.0 | 4.0 | 4.0 | 4.0 | 4.0 | — | — | — |
| | D-1 | 0.2 | 0.2 | 0.2 | 0.2 | 0.2 | 0.2 | 0.2 | — | 0.2 |
| | E-1 | — | — | — | — | — | — | 1.0 | — | — |
| | E-2 | 1.0 | 1.0 | 1.0 | 1.0 | 1.0 | 1.0 | — | — | 1.0 |
| | Ion-exchanged Water | 73.6 | 73.6 | 73.6 | 73.9 | 73.9 | 73.9 | 78.4 | 79.4 | 77.6 |
| | Total | 100.0 | 100.0 | 100.0 | 100.0 | 100.0 | 100.0 | 100.0 | 100.0 | 100.0 |
| (C) | Metal Ion Removal Method | — | A | B | — | A | B | — | — | — |
| | Na Metal Ion | 165 | 16 | 165 | 165 | 16 | 165 | 37 × 10⁶ | 980 | 165 |
| | Al Metal Ion | 7 | 1 | 5 | 7 | 1 | 5 | 470 | 480 | 7 |
| | Fe Metal Ion | 17 | 1 | 14 | 17 | 1 | 14 | 680 | 710 | 17 |
| | Zn Metal Ion | 13 | 1 | 8 | 13 | 1 | 8 | 610 | 650 | 13 |
| | Cu Metal Ion | 8 | 1 | 5 | 8 | 1 | 5 | 20 | 30 | 8 |
| | Ni Metal Ion | 5 | 1 | 4 | 5 | 1 | 4 | 40 | 50 | 5 |
| | Cr Metal Ion | 6 | 1 | 4 | 6 | 1 | 4 | 70 | 60 | 6 |
| | Pb Metal Ion | 6 | 1 | 3 | 6 | 1 | 3 | 90 | 100 | 6 |
| | Total of Metal Ions | 227 | 23 | 208 | 227 | 23 | 208 | >3000 | 3060 | 227 |
| | Melting Point (° C.) | 47 | 47 | 47 | 45 | 45 | 45 | 110 | 120 | 47 |
| Evaluation | Adhesion Performance | A | A | A | A | A | A | A | B | A |
| | Peel Performance | A | A | A | A | A | A | B | A | A |
| | Adhesion-stain Prevention Performance | A | AA | A | A | A | A | C | C | C |

Notes)
Details of the components used in these Examples and shown in Table 1 are as follows.
A-PEG1: Polyethylene glycol (mixture of 50 parts by mass of polyethylene glycol 1 (number-average molecular weight: 3,100, melting point: 55° C.) and 50 parts by mass of polyethylene glycol 2 (number-average molecular weight: 8,800, melting point: 60° C.)
A-PEG2: Polyethylene glycol (number-average molecular weight: 1,540, melting point: 45° C.)
A-Salt: Sodium salt of rosin-type thermoplastic resin (“Vinsol NVX (trade name)”, by Pinova Inc.)
A-Emulsion: Rosin-type resin (“Super Ester NS-121 (trade name)”, by Arakawa Chemical Industries, Ltd.)
B-1: Mannitol
D-1: Acetylene glycol-based surfactant (2,4,7,9-tetramethyl-5-decyne-4,7-diol ethylene oxide adduct represented by the general formula (2) where R²¹ and R²³ are methyl groups, R²² and R²⁴ are isobutyl groups, and A₂₁ and A₂₂ are single bonds (oxyethylene group recurring unit number: 4))
E-1: Alkylene oxide block copolymer (copolymer represented by ethylene oxide-propylene oxide-ethylene oxide triblock copolymer (HO—(EO)ₐ—(PO)₅₅—(EO)_{b}—H (a + b = 300) (EO: ethylene oxide, PO: propylene oxide)), number average molecular weight: 16500, ethylene oxide/propylene oxide (molar ratio) = 300/55)
E-2: Alkylene oxide block copolymer (ethylene oxide-propylene oxide diblock copolymer (copolymer represented by (HO—(EO)₁₅₀—(PO)₃₅—H (EO: ethylene oxide, PO: propylene oxide)), weight-average molecular weight: 9,400, ethylene oxide/propylene oxide (molar ratio) = 150/35)

From the results in Examples, it is known that the second water-based temporary fixing adhesive has excellent temporary fixing performance satisfying both adhesion performance and peel performance, and excellent coating performance and adhesion-stain prevention performance, and that, since the content of various metal ions is small, the adhesive is also excellent in functional decline prevention performance for various members and parts for use in optical devices and electronic devices. In addition, the adhesive uses the hydroxy group-having thermoplastic resin (A) as the resin component, the content of various metal ions therein can be controlled to fall in a predetermined range without metal ion removal treatment, and further by metal ion removal treatment using an ion exchanger, the content of various metal ions can be further reduced to be an extremely small amount, and consequently, the present invention can provide an adhesive extremely excellent in functional decline prevention performance for various members and parts for use in optical devices and electronic devices.

On the other hand, from the results of Comparative Examples 1-2 and 2-2, it is confirmed that, when the hydroxy group-having thermoplastic resin (A) is not used as the resin component, the total content of various metal ions could not be 3000 ppb or less, and from comparison between Comparative Example 3-2 and Examples, it is confirmed that by using the component (B), especially the adhesion-stain prevention performance can be improved.

### (Evaluation and Measurement Methods: Third Water-Based Temporary Fixing Adhesive)

### (1-3) Measurement of Surface Tension at 25° C.

The melting point of the adhesive obtained in Examples and Comparative Examples was measured according to JIS K0064:1992. Specifically, a sample dried by removing water from the adhesive obtained in Examples and Comparative Examples (a sample prepared by putting 2 ml of the adhesive in a small-size Petri dish having an inner diameter of 40 mm, and with no lid, drying it in a clean oven under the condition of 120° C. and 60 minutes) and A-PEG 1 used in these Examples each were melted by heating (temperature condition: 30 to 90° C.), then cooled (temperature condition: −20 to 30° C.) and thereafter ground into fine powder (maximum particle size: 300 μm), then the powder was dried in a desiccator for 24 hours, and the resultant sample was filled in a capillary (made of glass, inner diameter: 0.8 to 1.2 mm, thickness: 0.2 to 0.3 mm, length; 150 mm), and heated at a heating speed of 1° C./min. The melting temperature at which any solid could no more be recognized in visual observation (the temperature at which the powdery solid sample completely liquefied) is referred to as the melting point of the adhesive.

### (2-3) Measurement of Melting Point

The melting point of the adhesive obtained in Examples and Comparative Examples was measured according to the same method of the above “(1-1) Measurement of melting point”.

### (3-3) Measurement of Adhesion Strength

Five drops of the adhesive obtained in Examples and Comparative Examples were applied to one stainless substrate, dried under heat at 100° C. for 20 minutes, and then another stainless substrate was stuck thereto, cooled to room temperature, and after 20 minutes, the shear force of the bonded substrates was measured using a tensile strength measuring device according to “Test Method for Tensile Shear Adhesion Strength” defined in JIS K6850:1999.

### (4-3) Evaluation of Adhesion Performance

The adhesion strength measured in the above “(3-3) Measurement of adhesion strength” was evaluated according to the same method and based on the same criteria as in the above “(2-1) Evaluation of adhesion performance”. In the Examples, those given an evaluation rank B or higher were regarded as acceptable.

### (5-3) Evaluation of Peel Performance

The adhesives were evaluated according to the same method and based on the same criteria as in the above “(3-1) Evaluation of peel performance”. In the Examples, those given an evaluation rank B or higher were regarded as acceptable.

### (6-3) Evaluation of Coating Performance

The adhesives were evaluated according to the same method and based on the same criteria as in the above “(4-1) Evaluation of coating performance”. In the Examples, those given an evaluation rank B or higher were regarded as acceptable.

### (7-3) Evaluation of Adhesion-Stain Prevention Performance

The adhesives were evaluated according to the same method and based on the same criteria as in the above “(5-1) Evaluation of adhesion-stain prevention performance”. In the Examples, those given an evaluation rank B or higher were regarded as acceptable.

### (8-3) Evaluation of Cissing Prevention Performance

The adhesives were evaluated according to the same method and based on the same criteria as in the above “(6-1) Evaluation of cissing prevention performance”. In the Examples, those given an evaluation rank B or higher were regarded as acceptable.

### Examples 1-3 to 5-3, Comparative Examples 1-3 to 3-3

Adhesives were prepared in the blending ratio (% by mass) shown in Table 3. Ion water was used as the water-containing solvent (B). (The water content in the solvent is 100% by mass.) The surface tension of the resultant adhesives was measured according to the above method (1-3), the melting point was measured according to the above (2-3), the adhesion strength was measured according to the above method (3-3), and various properties were evaluated according to the above methods (4-3) to (8-3). The evaluation results are shown in Table 3.

TABLE 3

| | | Example | | | | | Comparative Example | | |
|---|---|---|---|---|---|---|---|---|---|
| | | 1-3 | 2-3 | 3-3 | 4-3 | 5-3 | 1-3 | 2-3 | 3-3 |
| (A) | A-PEG1 | 10.6 | 10.6 | 10.6 | — | — | 10.6 | — | — |
| | A-PEG2 | 10.6 | 10.6 | 10.6 | 10.6 | — | 10.6 | — | 10.6 |
| | A-PEG3 | — | — | — | 10.6 | — | — | — | 10.6 |
| | Resin Component 1 | — | — | — | — | 21.2 | — | — | — |
| | Resin Component 2 | — | — | — | — | — | — | 21.2 | — |
| (B) | B-1 | 1.0 | 4.0 | 8.0 | 4.0 | 4.0 | — | 4.0 | — |
| (D) | D-1 | 0.2 | 0.2 | 0.2 | 0.2 | 0.2 | 0.2 | 0.2 | — |
| (E) | E-1 | 1.0 | 1.0 | 1.0 | 1.0 | 1.0 | 1.0 | 1.0 | — |
| (C) | Ion-exchanged Water | 76.6 | 73.6 | 69.6 | 73.6 | 73.6 | 77.6 | 73.6 | 78.8 |
| | Total | 100.0 | 100.0 | 100.0 | 100.0 | 100.0 | 100.0 | 100.0 | 100.0 |
| | Surface Tension (mN/m) | 33 | 33 | 33 | 33 | 31 | 33 | 32 | 57 |
| | Adhesion Strength (MPa) | 0.8 | 0.8 | 0.8 | 1.2 | 12 | 0.8 | <0.1 | — |
| | Melting Point (° C.) | 47 | 47 | 47 | 58 | 62 | 47 | 110 | 58 |
| Evaluation | Adhesion Performance | A | A | A | A | A | A | C | — |
| | Peel Performance | A | A | A | A | B | A | — | — |
| | Coating Performance | A | A | A | A | A | A | A | C |
| | Adhesion-stain Prevention Performance | A | AA | A | A | A | C | C | C |
| | Cissing Prevention Performance | A | A | A | A | B | A | A | — |

Notes)
Details of the components used in these Examples and shown in Table 3 are as follows.
A-PEG1: Polyethylene glycol (number-average molecular weight: 1,000, melting point: 40° C., surface tension at 25° C.: 56 mN/m [20% aqueous solution])
A-PEG2: Polyethylene glycol (number-average molecular weight: 3,100, melting point: 55° C., surface tension at 25° C.: 56 mN/m [20% aqueous solution])
A-PEG3: Polyethylene glycol (number-average molecular weight: 8,800, melting point: 60° C., surface tension at 25° C.: 55 mN/m [20% aqueous solution])
Resin component 1: Ammonium-neutralized shellac resin (surface tension at 25° C.: 45 mN/m [20% aqueous solution], “Shellac KTA (trade name)”, by Koyo Chemical Co., Ltd.)
Resin component 2: Water-dissolved styrene-maleic acid resin (30% by mass) (surface tension at 25° C.: 41 mN/m [20% aqueous solution], “Arastar 703S (trade name)”, by Arakawa Chemical Industries, Ltd.)
B-1: Mannitol
D-1: Acetylene glycol-based surfactant (2,4,7,9-tetramethyl-5-decyne-4,7-diol ethylene oxide adduct represented by the general formula (2) where R₂₁ and R₂₃ are methyl groups, R₂₂ and R₂₄ are isobutyl groups, and A₂₁ and A₂₂ are single bonds (oxyethylene group recurring unit number: 4))
E-1: Alkylene oxide block copolymer (copolymer represented by ethylene oxide-propylene oxide-ethylene oxide triblock copolymer (HO—(EO)ₐ—(PO)₅₅—(EO)_{b}—H (a + b = 300) (EO: ethylene oxide, PO: propylene oxide)), number-average molecular weight: 16,500, ethylene oxide/propylene oxide (molar ratio) = 300/55)

From the results in Examples, it is confirmed that the third water-based temporary fixing adhesive has a predetermined surface tension and a predetermined adhesion strength, and is therefore excellent in temporary fixing performance satisfying both adhesion performance and peel performance, and in coating performance and adhesion-stain prevention performance and is also excellent in cissing prevention performance. As a result, highly accurate silicon wafers were obtained. In addition, the third water-based temporary fixing adhesive is a water-based adhesive not substantially containing an organic solvent, and therefore can reduce the load on the environment such as natural environments and working environments and is excellent in safety.

On the other hand, the adhesives of Comparative Examples 1-3 to 3-3 have a large or small surface tension, and can therefore have excellent coating performance and cannot have a temporary fixing function for silicon wafers. In addition, from comparison between Comparative Examples 1-3 and 3-3 with Examples, it is confirmed that, by using the component (B), especially the adhesion-stain prevention performance is improved.

### INDUSTRIAL APPLICABILITY

The water-based temporary fixing adhesive of the present invention is favorably used for applications that require temporary fixing performance of adhesives, for example, in temporary fixation on supports (temporary fixation) in various mechanical processing such as machining, polishing, cutting, grinding or drilling of various members and parts for use in various electronic devices such as OA devices, information devices and home electric appliances, as well as in other various devices such as optical devices, medical devices and automobile devices, for example, wafers such as silicon wafers, or optical lenses, sapphire, gallium arsenic, quartz, magnetic members, metal members, glass members, resin members or members for semiconductor devices.

1. A water-based temporary fixing adhesive comprising (A) a hydroxy group-having thermoplastic resin and (B) a glucide, wherein the glucide (B) is at least one selected from sugars and sugar alcohols.

2. The water-based temporary fixing adhesive according to claim 1, wherein the sugars are at least one selected from glucose, fructose, galactose, mannose, sucrose, lactose, maltose, trehalose and palatinose.

3. The water-based temporary fixing adhesive according to claim 1, wherein the sugar alcohols are at least one selected from sorbitol, mannitol, maltitol, xylitol, erythritol, pentaerythritol and lactitol.

4. The water-based temporary fixing adhesive according to claim 1, wherein the glucide (B) contains a sugar alcohol.

5. The water-based temporary fixing adhesive according to claim 1, wherein the glucide (B) is a sugar alcohol.

6. The water-based temporary fixing adhesive according to claim 1, wherein the sugar alcohol is mannitol.

7. The water-based temporary fixing adhesive according to claim 1, wherein the hydroxy group-having thermoplastic resin (A) contains at least a resin having a melting point, as measured according to JIS K0064:1992, of 30° C. or higher.

8. The water-based temporary fixing adhesive according to claim 1, wherein the hydroxy group-having thermoplastic resin (A) contains at least an oxyalkylene group-having resin.

9. The water-based temporary fixing adhesive according to claim 1, wherein the hydroxy group-having thermoplastic resin (A) contains at least one selected from a polyalkylene glycol and a polyalkylene glycol ester.

10. The water-based temporary fixing adhesive according to claim 1, wherein the content of the hydroxy group-having thermoplastic resin (A) is 5% by mass or more and 50% by mass or less based on the total amount of the composition.

11. The water-based temporary fixing adhesive according to claim 1, further containing a surface conditioner and a compatibilizer.

12. The water-based temporary fixing adhesive according to claim 1, wherein a total content of a sodium metal ion, an aluminum metal ion, an iron metal ion, a zinc metal ion, a copper metal ion, a nickel metal ion, a chromium metal ion and a lead metal ion is 3000 ppb or less, and the content of the sodium metal ion, the iron metal ion, the zinc metal ion and the copper metal ion is each individually 1000 ppb or less.

13. The water-based temporary fixing adhesive according to claim 1, further containing a water-containing solvent where water content in the solvent is 95% by mass or more, and having a surface tension at 25° C. of 20 mN/m or more and 55 mN/m or less and an adhesion strength of 0.1 MPa or more and 20 MPa or less.

14. A method for producing a member or a part comprising a temporary fixing step of temporarily fixing a precursor of a member or a part and a processing substrate using the water-based temporary fixing adhesive according to claim 1, and a processing step of mechanically processing the precursor to form a member or a part.

15. The method for producing a member or a part according to claim 14, wherein the precursor of a member or a part is a precursor of a member or a part for use in electronic devices.

16. The method for producing a member or a part according to claim 14, wherein the member or the part for use in electronic devices is a wafer, and the mechanical processing is polishing of the wafer surface.
